(19) United States
(12) Patent Application Publication
(10) Pub. No.: US 2020/0091016 A1
(43) Pub. Date: Mar. 19, 2020

(54) MANUFACTURING METHOD AND INSPECTION METHOD OF GROUP-III NITRIDE LAMINATE, AND GROUP-III NITRIDE LAMINATE

(71) Applicants: SUMITOMO CHEMICAL COMPANY, LIMITED, Tokyo (JP); SCIOCS COMPANY LIMITED, Ibaraki (JP); HOSEI UNIVERSITY, Tokyo (JP)

(72) Inventors: Fumimasa HORIKIRI, Ibaraki (JP); Tomoyoshi MISHIMA, Tokyo (JP)

(21) Appl. No.: 16/472,968

(22) PCT Filed: Nov. 9, 2017
(86) PCT No.: PCT/JP2017/040361

§ 371 Date: Jun. 24, 2019

(30) Foreign Application Priority Data
Dec. 27, 2016 (JP) 2016-253149

(51) Int. Cl. H01L 21/66; H01L 29/20; H01L 21/02; C30B 25/20; C30B 29/40; C23C 16/34; G01N 21/88; G01N 21/64

(52) U.S. Cl. CPC H01L 22/14; H01L 29/2003; H01L 21/0254; H01L 21/02389; G01N 21/64; C30B 29/406; C23C 16/34; G01N 21/88; C30B 25/20

(57) ABSTRACT

A manufacturing method of a group-III nitride laminate includes:
preparing a group-III nitride laminate having a group-III nitride substrate and a group-III nitride epitaxial layer formed above a main surface of the group-III nitride substrate; and
conducting photoluminescence mapping measurement at a plurality of measurement positions on the group-III nitride epitaxial layer, where a magnitude of an off-angle is different, the off-angle being formed by a normal direction of the main surface of the group-III nitride substrate and c-axis direction, to obtain a relative yellow intensity which is a rate of a yellow emission intensity to a band edge emission intensity, and obtain a correspondence relationship between a magnitude of the off-angle and the relative yellow intensity.

### TECHNICAL FIELD

The present invention relates to a manufacturing method and an inspection method of a group-III nitride laminate, and a group-III nitride laminate.

### BACKGROUND ART

A group-III nitride semiconductor such as gallium nitride (GaN) is useful as a raw material for a semiconductor device such as an optical device or an electronic device. A group-III nitride laminate in which an epitaxial layer (which may be hereinafter abbreviated as epi-layer) of the group-III nitride is formed above a group-III nitride substrate has the epi-layer superior in the crystal quality compared to a laminate in which an epi-layer is formed on a heterogeneous substrate such as sapphire (see, for example, Patent Documents 1 and 2, for constitution of a semiconductor device by growing an epi-layer on a group-III nitride substrate).

In a semiconductor device using the group-III nitride laminate, the crystal quality of the epi-layer has great effect on the operational performance of the device. Accordingly, technique to inspect the crystal quality of the epi-layer is important.

### CITED DOCUMENT

### Patent Document

Patent Document 1 Japanese Unexamined Patent Application Publication No. 2008-254970

Patent Document 2 Japanese Patent No. 5544723

### SUMMARY OF THE INVENTION

### Problems to be Solved by the Invention

An object of the present invention is to provide a technique which can be used to inspect the crystal quality of an epi-layer in a group-III nitride laminate.

### Means to Solve the Problem

According to an aspect of the present invention,

there is provided a manufacturing method of a group-III nitride laminate which includes:

preparing a first group-III nitride laminate having a first group-III nitride substrate and a first group-III nitride epitaxial layer formed above a main surface of the first group-III nitride substrate; and

conducting photoluminescence mapping measurement at a plurality of measurement positions on the first group-III nitride epitaxial layer, where a magnitude of an off-angle is different, the off-angle being formed by a normal direction of the main surface of the first group-III nitride substrate and c-axis direction, to obtain a relative yellow intensity which is a rate of a yellow emission intensity to a band edge emission intensity, and obtain a correspondence relationship between a magnitude of the off-angle and the relative yellow intensity.

According to another aspect of the present invention,

there is provided a group-III nitride laminate having a group-III nitride substrate and a group-III nitride epitaxial layer formed above a main surface of the group-III nitride substrate,

wherein, regarding a relative yellow intensity which is a rate of a yellow emission intensity to a band edge emission intensity in photoluminescence in the group-III nitride epitaxial layer,

a correspondence relationship between a magnitude of an off-angle formed by a normal direction of the main surface of the group-III nitride substrate and c-axis direction, and a relative yellow intensity has a tendency such that as the magnitude of the off-angle is increased, the relative yellow intensity is decreased, with a degree of the decrease in the relative yellow intensity becoming small.

### Advantageous Effect of the Invention

A correspondence relationship between the magnitude of the off-angle and the relative yellow intensity may be used to inspect crystal quality of the epi-layer in the group-III nitride laminate.

### BRIEF DESCRIPTION OF THE DRAWINGS

FIG. 1 is a flow chart illustrating a schematic flow of an inspection method according to an embodiment of the present invention.

FIG. 2(a) is a schematic cross-sectional view of a group-III nitride laminate, and FIG. 2(b) is a schematic cross-sectional view illustrating a state of PL mapping measurement on the group-III nitride laminate.

FIG. 3(a) is a schematically illustrated PL emission spectrum, and FIG. 3(b) is a graph schematically illustrating a correspondence relationship between an off-amount and a relative yellow intensity.

FIG. 4 is a flow chart illustrating a schematic flow of an inspection method according to a first variation of the embodiment of the present invention.

FIG. 5 is a flow chart illustrating a schematic flow of an inspection method according to a second variation of the embodiment of the present invention.

FIG. 6 is a flowchart illustrating a schematic flow of a method of estimating a physical amount according to an application example.

FIG. 7(a) is a schematic plan view illustrating an orientation of a hexagonal group-III nitride crystal, FIG. 7(b) is a schematic cross-sectional view illustrating an off-angle distribution of a substrate in an experimental example, and FIG. 7(c) is a schematic view illustrating off-angle distributions of an a-off substrate, an m-off substrate, and an m-off modified substrate in an experimental example.

FIG. 8 is a graph of an off-amount on a central line segment of each substrate in an experimental example plotted against a position on the substrate.

FIG. 9(a) is a schematic plan view illustrating a growth step of an epi-layer in an experimental example, and FIG. 9(b) is a schematic cross-sectional view illustrating a group-III nitride crystal in the experimental example.

FIG. 10(a) is a graph of a relative yellow intensity of a group-III nitride laminate in an experimental example plotted against a position on the substrate, and FIG. 10(b) is a graph of the relative yellow intensity of the group-III nitride laminate in the experimental example plotted against the off-amount.

FIG. 11(a) is a graph illustrating a carrier concentration (net donor concentration) and an acceptor concentration of the group-III nitride laminate in the experimental example plotted against the off-amount, and FIG. 11(b) is a graph illustrating the acceptor concentrations plotted against the relative yellow intensity.

FIG. 12 is a schematic view illustrating a group-III nitride laminate with a physical amount map.

### BEST MODE OF THE INVENTION

### Embodiments

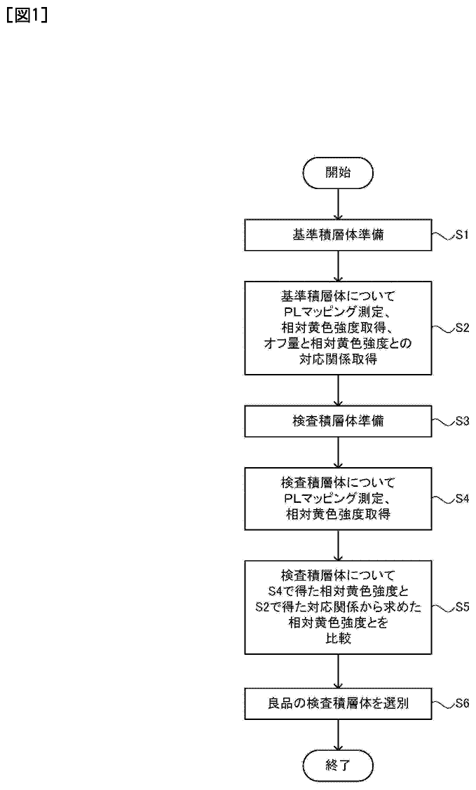

An inspection method of a group-III nitride laminate according to an embodiment of the present invention will be explained. FIG. 1 is a flow chart illustrating a schematic flow of the inspection method according to the embodiment of the present invention.

First, in step S1, a group-III nitride laminate 100 (hereinafter referred to as laminate 100 or reference laminate 100) is prepared which serves as a reference.

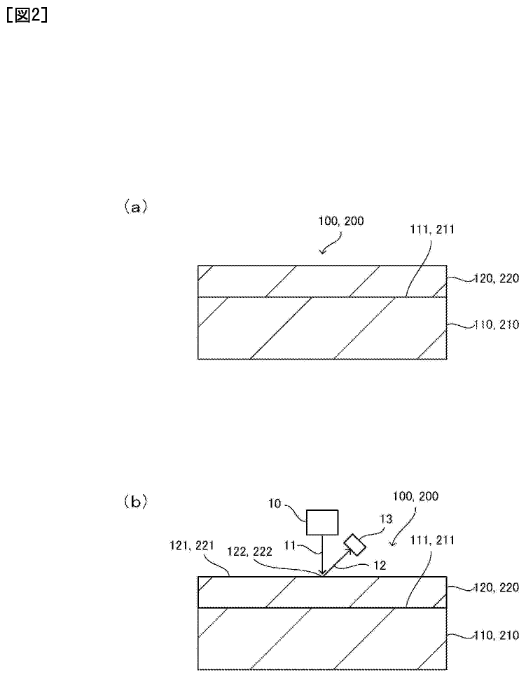

FIG. 2 (a) is a schematic cross-sectional view of the laminate 100. The laminate 100 includes a group-III nitride semiconductor. As the group-III nitride semiconductor, a gallium nitride (GaN)-based semiconductor, that is a semiconductor containing gallium (Ga) and nitrogen (N) may be used. Examples of the GaN-based semiconductor include, but not limited to, GaN. As the GaN-based semiconductor, one containing, in addition to Ga and N, a group-III element other than Ga as needed may be used.

Examples of the group-III element other than Ga include, for example, aluminum (Al) and indium (In). The group-III element other than Ga is preferably contained so that a lattice-mismatching in relation to GaN in the GaN-based semiconductor is 1% or less for the purpose of reducing lattice distortion. Example of an acceptable content in the GaN-based semiconductor is as follows: Al in AlGaN, 40 atm % or less of the group-III elements; and In in InGaN, 10 atm % or less of the group-III elements. InAlGaN may be InAlGaN obtained by combining InAlN in which In is 10 atm % or more and 30 atm % or less of the group-III elements and GaN at an arbitrary composition. With composition in which percentage of each of Al and In falls within the ranges shown above, a lattice distortion is unlikely to increase, suppressing occurrence of cracks.

The laminate 100 has the group-III nitride substrate 110 (hereinafter referred to as substrate 110) and the group-III nitride epitaxial layer 120 (hereinafter referred to as epi-layer 120) formed above the substrate 110. There may be an additional group-III nitride epitaxial layer intervening between the substrate 110 and the epi-layer 120. Preferred characteristics of the substrate 110 used for the laminate 100 will be described in detail later.

The substrate 110 has a main surface 111. An off-angle is an angle formed by a normal direction of the main surface 111 and c-axis direction of a group-III nitride crystal contained in the substrate 110. The off-angle is defined by an orientation and a magnitude. In this specification, the orientation of the off-angle is referred to as “off-direction” and the magnitude of the off-angle is referred to as “off-amount”.

The substrate 110 is a c-plane substrate. The phrase “the substrate 110 is a c-plane substrate” means that the off-amount is, for example 0° or more and 1.2° or less all over the main surface 111.

An off-angle distribution in the main surface 111 of the substrate 110 has been already obtained. In other words, at least one of the off-direction and the off-amount in the main surface 111 is known. Among them, the off-amount is known. In this case, measuring the off-angle distribution in the main surface 111 may be included in step S1. X-ray diffraction may be used for measurement of the off-angle distribution. When the substrate 110 with known off-angle distribution is used, measuring the off-angle distribution may not be included in step S1.

The epi-layer 120 is formed above the main surface 111 of the substrate 110 by metal organic vapor phase epitaxy (MOVPE or MOCVD, hereinafter referred to as MOVPE). As a result, carbon derived from a group-III organic source gas is unintentionally incorporated as an impurity in the epi-layer 120. In this case, a growth step of the epi-layer 120 may be included in step S1. When a laminate 100 above which an epi-layer 120 has been already formed is obtained for preparation of the laminate 100, the growth step of the epi-layer 120 may not be included in step S1.

The substrate 110 and the epi-layer 120 have n-type conductivity. As an n-type impurity, for example, silicon (Si), germanium (Ge) or the like may be used. The n-type impurity is added to the substrate 110, for example, at a concentration of 1×10¹⁸ cm⁻³ or more and 1×10¹⁹ cm⁻³ or less. The n-type impurity is added to the epi-layer 120, for example, at a concentration of 3×10¹⁵ cm⁻³ or more and 5×10¹⁶ cm⁻³ or less. The n-type impurity concentration in the epi-layer 120 is lower than the n-type impurity concentration of the substrate 110. The thickness of the substrate 110 is not particularly limited and is, for example, 400 μm. The thickness of the epi-layer 120 is, for example, 10 μm or more and 30 μm or less.

The epi-layer 120 corresponds to a drift layer when a semiconductor device such as a Schottky diode or a pn-junction diode is manufactured using the group-III nitride laminate similar to the laminate 100. The n-type impurity concentration of the epi-layer 120 is preferably not too low, for example, 3×10¹⁵ cm⁻³ or more, from the viewpoint of suppressing ON-resistance. Further, the n-type impurity concentration of the epi-layer 120 is preferably not too high, for example, 5×10¹⁶ cm⁻³ or less, and more preferably, less than 1×10¹⁶ cm ⁻³, from the viewpoint of enhancing pressure resistance. The thickness of the epi-layer 120 is preferably not too thin, preferably 10 μm or more, from the viewpoint of enhancing pressure resistance. In addition, the thickness of the epi-layer 120 is preferably not too thick, preferably 30 μm or less, from the viewpoint of suppressing ON-resistance.

As described above, in step S1, a laminate 100 having the substrate 110 and the epi-layer 120 formed above the main surface 111 of the substrate 110 is prepared.

Next, in step S2, photoluminescence (PL) mapping measurement is conducted on the laminate 100 to obtain a relative yellow intensity, thereby obtaining a correspondence relationship between an off-amount and the relative yellow intensity.

FIG. 2 (b) is a schematic cross-sectional view illustrating a state of PL mapping measurement on the laminate 100. PL mapping measurement is conducted on a micro area at a measurement position 122 defined on a surface 121 of the epi-layer 120, for example, on an area with a diameter of 5 μm to obtain PL emission spectrum at the measurement position 122. Excitation light 11 is irradiated from an excitation light source 10 to the measurement position 122, and PL light 12 is emitted. The PL light 12 is incident on a detector 13 and a PL emission spectrum corresponding to the measurement position 122 is obtained.

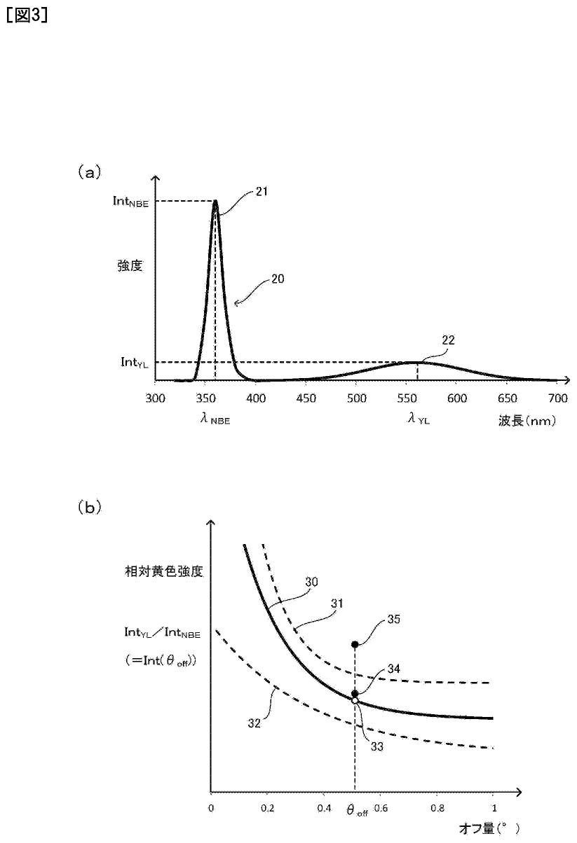

FIG. 3(a) is a schematically illustrated PL emission spectrum 20. A horizontal axis represents a wavenumber expressed in nm, and a vertical axis represents an intensity expressed in an arbitrary unit. The PL emission spectrum 20 has a band edge emission peak 21 and a yellow emission peak 22. The yellow emission peak 22 is considered to be a peak corresponding to a deep level caused by carbon which has been incorporated in the epi-layer 120, gallium hole or the like.

The peak wavelength λ_{NBE} of the band edge emission peak 21 may vary depending on the composition of the epi-layer 120. For example, in the case of GaN, the peak wavelength λ_{NBE} is 365 nm, and the corresponding energy is 3.4 eV. The peak wavelength λ_{YL} of the yellow emission peak 22 may vary depending on the composition of the epi-layer 120, growth conditions, or the like, but considered to be a wavelength within a range of 500 nm or more and 650 nm or less. For example, in the case of GaN, the peak wavelength λ_{YL} is 564 nm, and the corresponding energy is 2.2 eV. The band edge emission peak wavelength λ_{NBE} and the yellow emission peak wavelength λ_{YL} may vary depending on the amount of Al or In in the GaN-based semiconductor.

The peak 21 has an emission intensity Int_{NBE}, and the peak 22 has an emission intensity Int_{YL}. The relative yellow intensity Int_{YL}/Int_{NBE} is defined as a rate of the yellow emission intensity Int_{YL} relative to the band edge emission intensity Int_{NBE}.

A measurement position 122 and a position in the main surface 111 of the substrate 110 located thereunder can be considered as the same position in plan view. As the measurement position 122, a position is selected at which an off-amount in the main surface 111 is known. PL mapping is conducted on a plurality of measurement positions 122 where the off-amount is different. Since PL mapping measurement is conducted on the plurality of measurement positions 122, PL emission spectral distribution in the surface 121 may be obtained.

In this embodiment, measurement for obtaining a PL emission spectrum for one or more measurement positions is referred to as PL mapping measurement. Measurement for obtaining a PL emission spectrum is referred to as PL mapping measurement even when a PL emission spectrum for one measurement position is obtained without conducting scanning at the measurement position, in other words, without obtaining PL emission spectra corresponding to 2 or more measurement positions.

The relative yellow intensity is calculated for the PL emission spectrum obtained for each measurement position 122. Namely, the relative yellow intensity is calculated for each of the measurement positions 122 where the off-amount is different.

Then, the off-amount is associated with the relative yellow intensity to obtain a correspondence relationship between the off-amount and the relative yellow intensity.

FIG. 3 (b) is a graph schematically illustrating the correspondence relationship between the off-amount and the relative yellow intensity (sometimes referred to simply as “correspondence relationship” hereinafter). A horizontal axis represents an off-amount expressed in °, and a vertical axis represents a relative yellow intensity expressed in an arbitrary unit. A solid line 30 is a graph illustrating the correspondence relationship. Note that upper and lower dashed lines 31 and 32 represent boundaries of the allowable range described later.

The knowledge regarding the correspondence relationship described below is found by the inventors of the present invention, as described in detail in the following experimental example. The relative yellow intensity is determined depending on the off-amount, does not depend on the off-direction, that is, does not depend on whether the off-direction is in a-axis direction or in m-axis direction. In other words, the off-amount and the relative yellow intensity have a correspondence relationship which does not depend on the off-direction.

The correspondence relationship has a tendency such that as the off-amount is increased, the relative yellow intensity is decreased, with a degree of the decrease in the relative yellow intensity becoming small. Such a correspondence relationship is approximately expressed by the following equation (1), using exponential decay constant λ, critical off-amount θ₀ at which exponential function argument is zero, constant A to be multiplied by exponential function, and constant Int₀ to be added to exponential function:

[Eq. 1]

Int(θ_{off})=Aexp[−λ(θ_{off}−θ₀)]+Int₀ (1)

in the equation, θ_{off} represents an off-amount, and Int(θ_{off}) represents a relative yellow intensity.

As described above, in step S2, PL mapping measurement is conducted at a plurality of measurement positions on the laminate 100, where the off-amount is different, to obtain a relative yellow intensity which is a rate of a yellow emission intensity Int_{YL} to a band edge emission intensity Int_{NBE}. Then, a correspondence relationship between the off-amount and the relative yellow intensity is obtained.

Next, in step S3, the group-III nitride laminate 200 to be inspected (hereinafter referred to as laminate 200 or inspection laminate 200) is prepared.

As an inspection laminate 200, a laminate having a structure similar to that of the reference laminate 100 is used. Accordingly, FIG. 2(a) is referenced again for explanation. FIG. 2 (a) is a schematic cross-sectional view of the laminate 200. The laminate 200 has the group-III nitride epitaxial layer 220 (hereinafter referred to as epi-layer 220) formed above the main surface 211 of the group-III nitride substrate 210 (hereinafter referred to as substrate 210) by MOVPE.

From the viewpoint of applying the correspondence relationship obtained for the reference laminate 100 to the inspection of the inspection laminate 200, it is preferred to control the growth conditions of the epi-layer 220 of the inspection laminate 200 so that they are identical to the growth conditions of the epi-layer 120 of the reference laminate 100. In other words, it is preferred that a type of a supply gas such as a source gas, supply conditions of the supply gas such as a V/III rate, growth temperature, growth pressure or the like in MOVPE are controlled so that the growth of the epi-layer 120 of the reference laminate 100 is identical to the growth of the epi-layer 220 of the inspection laminate 200. It is difficult to completely conform the growth conditions of the epi-layer 120 to the growth conditions of the epi-layer 220. Therefore, it is preferable for them to be substantially identical within an acceptable error range.

The n-type impurity concentration is preferably controlled so as to be identical between the epi-layer 120 and the epi-layer 220. The error of the n-type impurity concentration in the epi-layer 220 with respect to the n-type impurity concentration in the epi-layer 120 is preferably within ±2%. The thickness of the layer is preferably controlled so as to be identical between the epi-layer 120 and the epi-layer 220. The error of the thickness of the epi-layer 220 with respect to the thickness of the epi-layer 120 is preferably within ±5%.

An off-angle distribution in the main surface 211 of the substrate 210 has been already obtained. In other words, at least one of the off-direction and the off-amount in the main surface 211 is known. Among them, the off-amount is known. In this case, measuring the off-angle distribution in the main surface 211 may be included in step S3. X-ray diffraction may be used for measurement of the off-angle distribution. When the substrate 210 with known off-angle distribution is used, measuring the off-angle distribution may not be included in step S3.

A growth step of the epi-layer 220 may be included in step S3. When the laminate 200 in which the epi-layer 220 has been already formed is obtained for preparation of the laminate 200, the growth step of the epi-layer 220 may not be included in step S3.

As described above, in step S3, a laminate 200 having the substrate 210 and the epi-layer 220 formed above the main surface 211 of the substrate 210 is prepared.

Next, in step S4, PL mapping measurement is conducted on the laminate 200 to obtain a relative yellow intensity.

The PL mapping measurement is essentially similar to the PL mapping measurement for the laminate 100. Accordingly, FIG. 2(b) is referenced again for explanation. Measurement conditions, such as wavelength, power, and spot size of an excitation light are preferably controlled so as to be identical to those for the laminate 100. In PL mapping measurement, PL emission spectrum at the measurement position 222 defined on a surface 221 of an epi-layer 220 is obtained. PL mapping is conducted on at least one inspection position 222.

An inspection position 222 and a position in the main surface 211 of the substrate 210 located thereunder can be considered as the same position in plan view. As the inspection position 222, a position is selected at which an off-amount in the main surface 211 is known. The off-amount at the inspection position 222 is referred to as the inspection position off-amount.

The relative yellow intensity is calculated for the PL emission spectrum obtained for the inspection position 222. Namely, the relative yellow intensity is calculated for the measurement position 222 having the inspection position off-amount.

As described above, in step S4, PL mapping measurement is conducted on the inspection position 222 of the laminate 200 to obtain the relative yellow intensity.

Next, in step S5, the relative yellow intensity obtained in step S4 is compared with the relative yellow intensity obtained from the correspondence relationship obtained in step S2, for the laminate 200.

The relative yellow intensity may be obtained from the correspondence relationship obtained in step S2 as follows. The relative yellow intensity is calculated for the inspection position 222 from the inspection position off-amount based on the correspondence relationship. More specifically, the inspection position off-amount θ_{off} is assigned to equation (1) to calculate the relative yellow intensity Int(θ_{off}) at the inspection position 222.

Referring to FIG. 3(b) again, two comparative examples will be explained. An open circle 33 represents the relative yellow intensity (referred to as relative yellow intensity 33) calculated from the inspection position off-amount θ_{off} based on the correspondence relationship. Filled circles 34, 35 represent the relative yellow intensity obtained from PL mapping measurement at the inspection position 222 in step S4 expressed as a value relative to the inspection position off-amount θ_{off}. The filled circle 34 represents a relative yellow intensity of a first example (referred to as relative yellow intensity 34), and the filled circle 35 represents a relative yellow intensity of a second example (referred to as relative yellow intensity 35).

The first example is an example in which the relative yellow intensity 34 obtained from PL mapping measurement well coincides with the relative yellow intensity 33 obtained from the correspondence relationship (difference is within the acceptable range). When the relative yellow intensity 34 well coincides with the relative yellow intensity 33, it is determined that the crystal growth at the inspection position 222 in the epi-layer 220 of the laminate 200 has been normally conducted. In other words, crystal quality of the epi-layer 220 is determined as good.

The second example is an example in which the relative yellow intensity 35 obtained from PL mapping measurement greatly deviates from the relative yellow intensity 33 obtained from the correspondence relationship and the difference is out of the acceptable error range. When the relative yellow intensity 35 greatly deviates from the relative yellow intensity 33, it is determined that the crystal growth at the inspection position 222 in the epi-layer 220 of the laminate 200 has not been normally conducted.

The acceptable range of the difference from the relative yellow intensity 33 may be set as needed. In this example, the area between the dashed line 31 and the dashed line 32 represents the acceptable range. The dashed line 31 and the dashed line 32 are curves in which the parameters λ, A, Int₀ in the equation (1) are respectively 50% greater than and 50% smaller than the parameters λ, A, Int₀ representing the solid line 30.

For example, there may be cases where crystal growth is not normally conducted due to insufficient decomposition of the group-III organic source gas, peeling of the silicon carbide (SiC) coating from the susceptor of the crystal growth device, or the like. In such a case, since the concentration of carbon incorporated in the epi-layer 220 is greatly increased, the relative yellow intensity becomes stronger and upward deviation from the correspondence relationship (solid line 30) becomes larger. When some abnormality is presumed because of many inspection positions where the relative yellow intensity deviates from the acceptable range, it is recommended to inspect and adjust the crystal growth conditions and the crystal growth device.

On the other hand, a large downward deviation from the correspondence relationship (solid line 30), that is, reduced relative yellow intensity may be interpreted also as the epi-layer 220 having good crystal quality, which may possibly occur although rarely. When the downward deviation is large, inspection or adjustment may be conducted on the PL mapping measurement device or the like in addition to the crystal growth conditions and the crystal growth device.

As described above, in step S5, the relative yellow intensity obtained from PL mapping measurement at the inspection position 222 in the laminate 200 is compared with the relative yellow intensity obtained from the correspondence relationship for the inspection position off-amount.

Next, in step S6, the laminate 200 which is determined that normal crystal growth of the epi-layer 220 has been conducted is selected as a non-defective product based on the comparison in step S5. The laminate 200 selected as the non-defective product is supplied as a material for manufacturing a semiconductor device. In the step which is conducted after step S6 to manufacture a semiconductor device, the step of forming an electrode above the epi-layer 220 and the like is conducted.

In this way, the inspection methods of the group-III nitride laminate according to the embodiment is conducted. According to the inspection method of the embodiment, using the correspondence relationship between the off-amount and the relative yellow intensity enables inspection on whether the crystal growth of the epi-layer 220 of the inspection laminate 200 has been normally conducted or not. When it is determined that crystal growth has been normally conducted, the inspection laminate 200 as being a non-defective product can be supplied as a material for the semiconductor device. On the other hand, when it is determined that crystal growth has not been normally conducted, for example, inspection and adjustment of growth conditions, a crystal growth device, or the like can be further conducted. The number of the inspection positions 222 in the inspection laminate 200 may be one or two or more. Since the inspection method of the embodiment can be conducted using PL mapping measurement at the inspection position 222, it can be conducted nondestructively and easily.

It should be noted that the number of the reference laminates 100 used to obtain the correspondence relationship may be one, or two or more, i.e., plural, as in an experimental example described later. Since a plurality of the laminates 100 are used, it becomes easier to obtain the correspondence relationship with a high accuracy for a wide range of off-amounts compared to the case of using only one laminate 100, as will be described later.

The order of steps S1 to S5 illustrated in the flowchart of FIG. 1 may be changed as appropriate. Step S1 of preparing the laminate 100 just have to be conducted before step S2 of conducting PL mapping measurement and the like on the laminate 100. Step S3 of preparing the laminate 200 just have to be conducted before step S4 of conducting PL mapping measurement and the like on the laminate 200. Step S2 of obtaining the correspondence relationship and step S4 of obtaining the relative yellow intensity from the PL mapping measurement on the laminate 200 just have to be conducted before step S5 of comparing the relative yellow intensity obtained from PL mapping measurement on the laminate 200 with the relative yellow intensity obtained from the correspondence relationship. It does not matter which of step S2 of obtaining the correspondence relationship and step S4 of obtaining the relative yellow intensity from the PL mapping measurement on the laminate 200 is conducted first.

The laminate 100 may be identified as a group-III nitride laminate in which, regarding the relative yellow intensity of the epi-layer 120, the correspondence relationship between the off-amount and the relative yellow intensity has a tendency such that as off-amount is increased, the relative yellow intensity is decreased, with a degree of the decrease in the relative yellow intensity becoming small.

Next, the manufacturing method of the substrate 110 will be explained. Preferred characteristics of the substrate 110 used for the laminate 100 will be explained in detail. Hydride vapor phase epitaxy (HVPE) using void-assisted separation (VAS) method is conducted to manufacture the substrate 110.

First, an underlayer is formed on a growth substrate in VAS method. For example, a sapphire substrate is used as a growth substrate. As the underlayer, for example, a low temperature-growing GaN buffer layer and a Si-doped GaN layer are formed by metal organic vapor phase epitaxy. Next, a metal layer is formed on the underlayer. As the metal layer, for example, a titanium layer is formed by vapor deposition.

Next, the metal layer is heat-treated in an atmosphere containing a nitriding agent gas for nitriding to form a metal nitride layer having a high density of fine holes on the surface. Further, the underlayer is partly etched through the holes of the metal nitride layer upon the heat treatment, forming a void-containing underlayer.

In order to obtain a preferred substrate 110 for use in the laminate 100, in this example, the heat treatment has the following features. The heat treatment is conducted such that the “void formation rate (volume void rate)”, which is a volume rate of voids occupying the void-containing underlayer, is uniformized circumferentially on the growth substrate. Specifically, for example, the susceptor on which the growth substrate is to be mounted is rotated to conduct circumferentially uniform heat treatment. Alternatively, for example, the heating status of the heater in the plane of the growth substrate is adjusted to circumferentially uniformize the temperature distribution in the growth substrate.

Furthermore, the heat treatment is conducted such that the void formation rate of the void-containing underlayer increases in the radial direction from the center toward the outer peripheral of the growth substrate. Specifically, for example, the heating status of the heater in the plane of the growth substrate is adjusted so that the temperature of the growth substrate monotonically increases in the radial direction from the center toward the outer periphery.

Next, the Si-doped GaN layer is grown by HVPE as a thick full-growth layer on the void-containing underlayer and on the metal nitride layer of the growth substrate. In this growth, a gap derived from the void present in the void-containing underlayer is formed between the full-growth layer and the metal nitride layer. Since the void formation rate of the void-containing underlayer is controlled as described above, the gaps are formed to be uniform in the circumferential direction and to become larger outwardly from the center in the radial direction.

In the cooling process after the growth of the full-growth layer is completed, the full-growth layer is spontaneously peeled from the growth substrate at the gap formed between the metal nitride layer and the full-growth layer. Since the gap is formed to be uniform in the circumferential direction and to become larger outwardly from the center in the radial direction, the full-growth cell may be peeled uniformly in the circumferential direction while peeling proceeds from the outer periphery toward the center of the growth substrate. The full-growth layer after peeling is sliced to obtain the substrate 110.

In the full-growth layer, the defect density on the growth surface side (front surface side) is low and the defect density on the growth substrate side (back surface side) is high. Due to such defect density difference, the peeled full-growth layer warps to become concave on the front surface side. An off-angle distribution is generated on the main surface of the substrate 110 obtained by slicing the full-growth layer which has warped in such a manner.

The substrate 110 manufactured by VAS method as described above is preferably used for the laminate 100 because of at least two reasons described below. First, the substrate 110 is preferable in that the main surface 111 does not have an area with extremely high defect density. Accordingly, the laminate 100 having the aforementioned correspondence relationship between the off-amount and the relative yellow intensity can be obtained.

When the substrate is used in which a region with an extremely high defect density exists on the main surface, the epi-layer grown on such a region will have increased relative yellow intensity because of its poor crystal quality. For this reason, the area with extremely high defect density and the other area will differ greatly in their relative yellow density even if they have the same off-amount. Therefore, the aforementioned correspondence relationship between the off-amount and the relative yellow density cannot be obtained.

Specifically, preferred conditions for the defect density are as follows, for example. When the observation area on the main surface 111 of the substrate 110 is scanned and measured in a measurement area of 3×3-millimeter squares according to a cathodoluminescence (CL) method, the maximum defect density is 5×10⁶ cm⁻² or less. The maximum defect density is more preferably equal to or less than 10 times the average defect density, and still more preferably equal to or less than 10 times the minimum defect density. One example of the maximum defect density is 4.7×10⁶ cm⁻².

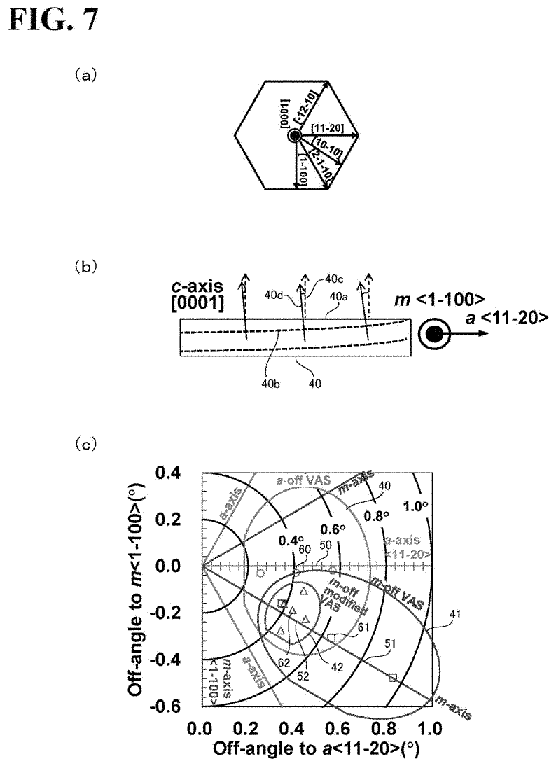

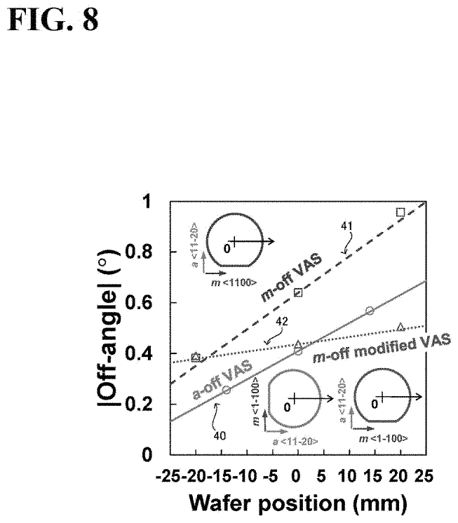

Secondly, the substrate 110 is preferred in that it has the off-angle distribution as follows. Given a certain position A on the main surface 111 of the substrate 110, the position A is defined, for example, at the center of the substrate 110 (hereinafter referred to as substrate center), but it may be defined at the position other than the substrate center. In a circular substrate having a cutaway portion such as an orientation flat, the substrate center coincides with a center of a circle created by filling the cutaway portion. Given a line segment B passing through the position A and parallel to the off-direction at the position A on the main surface 111, the off-direction at each of the position located on the line segment B coincides with the off-direction at the position A (parallel to the line segment B) and the off-amount varies monotonically from one end toward the other end of the line segment B in proportion to the distance from the one end (see FIGS. 7(c) and 8).

In the aforementioned method, since the gap between the full-growth layer and the metal nitride layer is formed to be uniform in the circumferential direction and to be larger outwardly from the center in the radial direction, the full-growth layer is allowed to be peeled uniformly in the circumferential direction from the outer periphery toward the center of the growth substrate. Since such a gap is formed, the generation of excessive local stress in the plane is also suppressed in the full-growth layer being growing.

Since the full-growth layer is grown and peeled in this way, it is possible to obtain a substrate 110 in which the off-angle distribution varies smoothly and continuously. More specifically, it is possible to obtain the substrate 110 having the off-amount which varies proportionally as described above.

Since the substrate 110 has such an off-angle distribution and does not have an area with extremely high defect density, an in-plane distribution of the physical amount, among them, the physical amount which tends to monotonically vary depending on the off-amount such as the relative yellow density, of the epi-layer 120 to be grown on the substrate 110 may become a distribution which tends to vary smoothly and continuously. Therefore, areas in which the epi-layers 120 have the similar physical amount can be collectively provided as a large area to the laminate 100. The laminate 100 having such characteristics is preferred as a material for manufacturing a semiconductor device.

Although the preferred features of the laminate and the substrate have been explained taking the reference laminate 100 and the substrate 110 as an example, such features are similar to those of the inspection laminate 200 and the substrate 210.

### First Variation

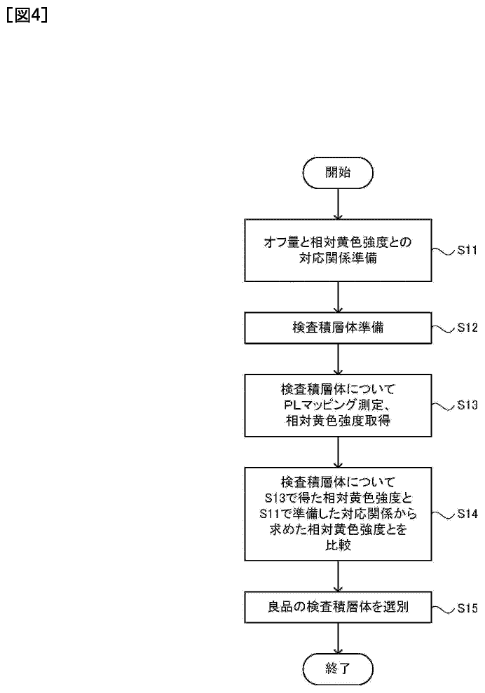

Next, an inspection method of the group-III nitride laminate according to a first variation of the aforementioned embodiment will be explained. FIG. 4 is a flow chart illustrating a schematic flow of the inspection method according to the first variation.

In the aforementioned embodiment, an example is explained in which PL mapping measurement is firstly conducted on the laminate 100 to obtain a correspondence relationship between the off-amount and the relative yellow intensity (steps S1, S2). Once a correspondence relationship is obtained, for example, it can be compiled in a database and repeatedly used. The first variation contemplates an embodiment of utilizing a previously obtained correspondence relationship as described above.

First, in step S11, the correspondence relationship between the off-amount and the relative yellow intensity is prepared. The correspondence relationship is prepared, for example, in the form of a database.

The subsequent steps S12 to S15 are similar to steps S3 to S6 in the aforementioned embodiment. Namely, PL mapping measurement is conducted on the inspection position 222 of the laminate 200 to obtain the relative yellow intensity. Then, the relative yellow intensity obtained by PL mapping measurement is compared with the relative yellow intensity obtained from the correspondence relationship to select the non-defective laminate 200.

According to the first variation, for example, the operation of conducting PL mapping measurement of the reference laminate 100 prior to PL mapping measurement of the inspection laminate 200 to obtain the correspondence relationship can be omitted, promoting efficiency of the inspection.

The order of steps S11 to S14 illustrated in the flowchart of FIG. 4 may be changed as appropriate. Step S12 of preparing the laminate 200 just have to be conducted before step S13 of conducting PL mapping measurement and the like on the laminate 200. Step S11 of preparing the correspondence relationship and step S13 of obtaining the relative yellow intensity from the PL mapping measurement on the laminate 200 just have to be conducted before step S14 of comparing the relative yellow intensity obtained from PL mapping measurement on the laminate 200 with the relative yellow intensity obtained from the correspondence relationship. It does not matter which of step S11 of preparing the correspondence relationship and step S13 of obtaining the relative yellow intensity from the PL mapping measurement on the laminate 200 is conducted first.

It should be noted that the step of preparing the correspondence relationship (step S11 of the first modified example) may be considered to also encompasses conducting PL mapping measurement on the reference laminate 100 or the like to obtain the correspondence relationship (steps S1 and S2 of the aforementioned embodiment). In this case, the aforementioned embodiment may also be included in the first variation.

### Second Variation

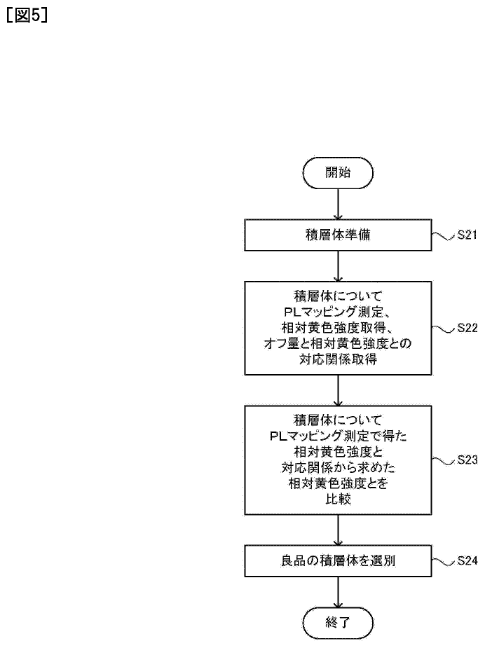

Next, an inspection method of the group-III nitride laminate according to a second variation of the aforementioned embodiment will be explained. FIG. 5 is a flow chart illustrating a schematic flow of the inspection method according to a second variation.

In the aforementioned embodiment, an example has been explained in which the correspondence relationship for the reference laminate 100 is obtained (steps S1 and S2) and the inspection laminate 200 which is another laminate is inspected (steps S3 to S5). The epi-layer 120 of the reference laminate 100 preferably has a good crystal quality but may have a poor crystal quality in some cases depending on the measurement positions 122. Therefore, the correspondence relationship is obtained for the laminate 100, and the laminate 100 may be subjected to inspection. In the second variation, it is contemplated that the reference laminate 100 used to obtain the correspondence relationship also serves as an inspection laminate to be inspected.

In the second variation, a laminate 100 is firstly prepared in steps S21 and S22 as in steps S1 and S2 of the aforementioned embodiment, then PL mapping measurement is conducted on the laminate 100 to obtain a relative yellow intensity, thereby obtaining a correspondence relationship between an off-amount and the relative yellow intensity.

Next, a particular measurement position 122 is taken as an inspection position, and the relative yellow intensity obtained by PL mapping measurement at the inspection position is compared with the relative yellow intensity obtained from the correspondence relationship in step S23. In step S24, a non-defective inspection laminate 100 is selected.

The principle of comparison is similar to that explained for the inspection position 222 of the laminate 200 in the aforementioned embodiment. When the relative yellow intensity obtained from PL mapping well coincides with the relative yellow intensity obtained from the correspondence relationship, it is determined that the crystal growth at the measurement position (inspection position) 122 has been normally conducted. On the contrary, when the relative yellow intensity obtained from PL mapping greatly deviates from the relative yellow intensity obtained from the correspondence relationship, it is determined that the crystal growth at the measurement position (inspection position) 122 has not been normally conducted.

According to the second variation, it is possible to obtain the correspondence relationship and to inspect the crystal quality at the individual measurement position (inspection position) 122, for the laminate 100.

As explained above, the inspection methods of the group-III nitride laminate according to the embodiment and the first and second variations thereof may be conducted. The inspection method according to the embodiment and the first and second variations thereof can be regarded also as evaluation methods of the group-III nitride laminate. Further, the inspection methods according to the embodiment and the first and second variations thereof may be conducted as at least a part of a manufacturing method of the group-III nitride laminate, or at least a part of a manufacturing method of a semiconductor device using the group-III nitride laminate. Therefore, such a method can be regarded as a manufacturing method of the group-III nitride laminate or as a manufacturing method of the semiconductor device.

### Application Example

The correspondence relationship between the off-amount and the relative yellow intensity can be utilized to inspect the crystal quality of the epi-layer at the inspection position using the relative yellow intensity as described above. As another embodiment, the correspondence relationship may be applied as follows.

For example, the following applications can be proposed. Capacitance-voltage (C-V) measurement may be conducted on the epi-layer of the group-III nitride laminate to measure the carrier concentration (net donor concentration). The acceptor concentration can also be obtained by C-V measurement as explained in the following experimental example. C-V measurement may be conducted on a plurality of measurement positions where the off-amount is different to obtain a correspondence relationship between the off-amount and the carrier concentration (or between the off-amount and the acceptor concentration). The correspondence relationship may be associated with the correspondence relationship between the off-amount and the relative yellow intensity using the off-amount to obtain the correspondence relationship between the relative yellow intensity and the carrier concentration (acceptor concentration). Therefore, when C-V measurement is conducted on the epi-layer of the reference laminate in advance, the carrier concentration (acceptor concentration) may be estimated by obtaining the relative yellow intensity by PL mapping measurement at the inspection position in the epi-layer of the inspection laminate without conducting C-V measurement.

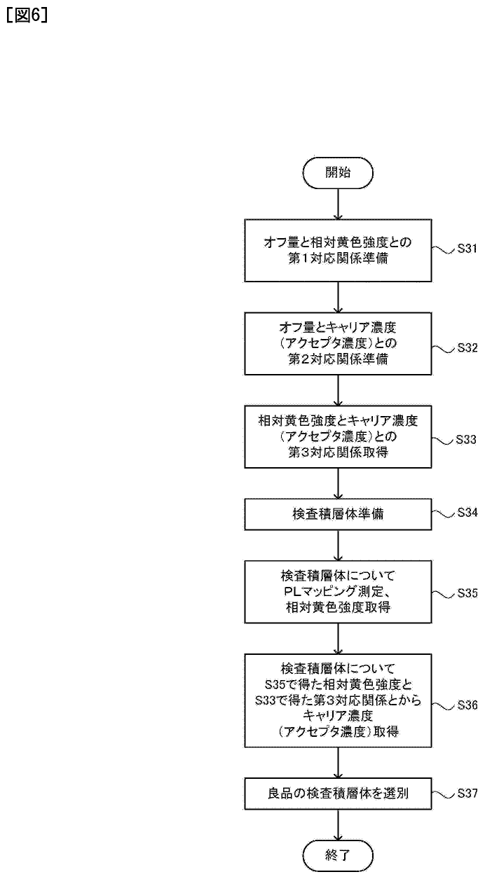

FIG. 6 is a flowchart illustrating a schematic flow of a method of estimating the carrier concentration (acceptor concentration) according to such an application example. In step S31, the first correspondence relationship which is a correspondence relationship between the off-amount and the relative yellow intensity is prepared. The first correspondence relationship may be prepared from measurement on the reference laminate or in the form of a database. In step S32, the second correspondence relationship which is a correspondence relationship between the off-amount and the carrier concentration (acceptor concentration) is prepared. The second correspondence relationship may be prepared from measurement on the reference laminate or in the form of a database. In step S33, the first correspondence relationship is associated with the second correspondence relationship using the off-amount to obtain a third correspondence relationship which is a correspondence relationship between the relative yellow intensity and the carrier concentration (acceptor concentration). Note that, it does not matter which of step S31 and step S32 is conducted first. Alternatively, steps S31 and S32 may be omitted, and the third correspondence relationship prepared in the form of a database in advance may be used in step S33.

In step S34, an inspection laminate is prepared. In step S35, PL mapping measurement is conducted on the inspection position of the inspection laminate to obtain a relative yellow intensity. In step S36, the carrier concentration (acceptor concentration) is obtained based on the relative yellow intensity obtained in step S35 and the third correspondence relationship obtained in step S33. In step S37, the inspection laminate which is a non-defective product is selected whose carrier concentration (acceptor concentration) satisfies the predetermined condition.

Further, for example, the following applications can be proposed. Secondary ion mass spectrometry (SIMS) measurement may be conducted on the epi-layer of the group-III nitride laminate to measure the concentration of carbon or the like. SIMS measurement may be conducted on a plurality of measurement positions where the off-amount is different to obtain a correspondence relationship between the off-amounts and the concentration of carbon or the like. Since the correspondence relationship may be associated with the correspondence relationship between the off-amount and the relative yellow intensity using the off-amount, the concentration of carbon or the like can be estimated from the relative yellow intensity obtained by PL mapping, based on the idea similar to the aforementioned C-V measurement, without conducting SIMS measurement.

Regarding a physical amount which can be obtained not only by C-V measurement or SIMS measurement but also by deep level transient spectroscopy (DLTS) measurement, for example, the correspondence relationship between the off-amount and the physical amount may be associated with the correspondence relationship between the off-amount and the relative yellow intensity using the off-amount to obtain the correspondence relationship between the relative yellow intensity and the physical amount, enabling estimation of the physical amount from the relative yellow intensity.

### Experimental Example

Next, an experimental example will be explained. In this experimental example, a laminate including an epi-layer grown above the substrate was investigated for the relationship between the off-angle and the relative yellow intensity. Three types of substrates manufactured by the aforementioned VAS method were used as substrates. First, the substrates will be explained.

FIG. 7 (a) is a schematic plan view illustrating the orientation of the hexagonal group-III nitride crystal. Examples of a-axis direction include [11-20] orientation, [−12-10] orientation, and [2-1-10] orientation, and examples of m-axis direction include [10-10] orientation and [1-100] orientation. C-axis direction is [0001] orientation.

FIG. 7 (b) is a schematic cross-sectional view illustrating an off-angle distribution of the substrate 40. A cross-sectional view taken along a line passing through the substrate center and parallel to a-axis direction is illustrated. A substrate (a-off substrate described later) 40 in which the off-direction at the substrate center is parallel to a-axis direction is illustrated. The substrate 40 has a main surface 40a. A c-plane 40b of the group-III nitride crystal included in the substrate 40 is indicated by a dashed line. An angle formed by a normal direction 40c of the main surface 40a and c-axis direction 40d is an off-angle. Due to the c-plane 40b being curved, there is an off-angle distribution generated in the main surface 40a. Since the off-angle distribution is generated, that is, since c-axis direction 40d of the crystal varies in the main surface 40a, a-axis direction of the crystal also varies. Namely, the inclination of a-axis direction of the crystal from the major surface 40a varies. In the present specification, in order to avoid complicated explanation, the term “a-axis direction” used with reference to the off-direction of the a-off substrate refers to the direction which is a-axis direction of the crystal projected on the main surface 40a (direction parallel to the main surface 40a), rather than a-axis direction of the crystal per se. The same applies to the “m-axis direction” with respect to the off-direction of the m-off substrate described later.

In this experimental example, a substrate in which the off-direction of the substrate center was parallel to a-axis direction (referred to as a-off substrate) and a substrate in which the off-direction of the substrate center was parallel to m-axis direction (referred to as m-off substrate) were used. One a-off substrate and two m-off substrates were used. One of the two m-off substrates has a smaller off-angle distribution (which is referred to as m-off modified substrate). The m-off modified substrate may be obtained by growing a thicker film by HVPE than in the case of producing an ordinary m-off substrate.

FIG. 7(c) is a schematic view illustrating an off-angle distribution of each of the a-off substrate 40, the m-off substrate 41, and the m-off modified substrate 42. In this figure, the a-off substrate is indicated as “a-off VAS”, the m-off substrate is indicated as “m-off VAS”, and the m-off modified substrate is indicated as “m-off modified VAS”.

Taking a point where the off-angle (off-amount) is zero as an origin, a-axis direction and m-axis direction are shown extending radially from the origin, and the off-amount is indicated in proportion to the distance from the origin. The positions where the off-amount is 0.2°, 0.4°, 0.6°, 0.8° and 1.0° respectively are indicated concentrically.

Each of the a-off substrate 40, the m-off substrate 41, and the m-off modified substrate 42 is a circular substrate having an orientation flat at an end portion in a-axis direction. Although each of the substrates 40 to 42 is a circular substrate, it is indicated as being elliptically deformed due to the polar coordinate-like display in FIG. 7(c). To be more precise, a portion farther from the origin (a portion having a greater off-amount) is indicated being stretched. Since the m-off modified substrate 42 has a smaller off-angle distribution compared to the m-off substrate 41, the contour of the m-off modified substrate 42 is displayed smaller than the contour of the m-off substrate 41.

An off-direction and an off-amount of an off-angle are shown as a position within the contour of each of the substrates 40 to 42. For each of the substrates 40 to 42, the origin is located outside the contour. Thus, each of the substrates 40 to 42 does not have a position where the off-angle is zero (off-amount is zero) all over the main surface. The substrates 40 to 42 may be hereinafter referred to simply as substrates when no particular distinction is made among them.

The off-direction at a certain position A on the main surface of the substrate means the direction from the position A toward the origin. Given a line segment B passing through the position A and parallel to the off-direction at the position A, the off-direction at each of the position located on the line segment B coincides with the off-direction at the position A (parallel to the line segment B). Since the substrate has no position where the off-angle (off-amount) is zero, the off-direction does not invert on the line segment B (for example, does not invert from positive a-axis direction to negative a-axis direction).

The off-amount at the position A is proportional to the distance from the origin to the position A. Since the substrate has no position where the off-angle (off-amount) is zero at each of the positions located on the line segment B, the off-amount varies monotonically from one end toward the other end of the line segment B in proportion to the distance from the one end (for example, increases monotonically from the end closer to the origin toward the farther end of the line segment B and in proportion to the distance from the end closer to the origin).

In the a-off substrate 40, the off-direction at the substrate center (as an example of the position A) is parallel to a-axis direction. A line segment passing through the substrate center and parallel to the off-direction (as an example of the line segment B) is referred to as a center line segment 50. At each of the positions on the center line segment 50, the off-direction is identical, that is, parallel to a-axis direction. The actual measurement values of the off-angles in the a-off substrate 40 are shown by circles. These circles represent the off-angles at the positions on the central line segment 50 within the error range. The central circle 60 represents the substrate center. The off-amount at the substrate center is 0.41°.

In the m-off substrate 41, the off-direction at the substrate center (as an example of the position A) is parallel to m-axis direction. A line segment passing through the substrate center and parallel to the off-direction at the substrate center (as an example of the line segment B) is referred to as a center line segment 51. At each of the positions on the center line segment 51, the off-direction is identical, that is, parallel to m-axis direction. The actual measurement values of the off-angles in the m-off substrate 41 are shown by squares. These squares represent the off-angles of the positions on the central line segment 51 within the error range. The central square 61 represents the substrate center. The off-amount at the substrate center is 0.64°.

In the m-off modified substrate 42, the off-direction at the substrate center (as an example of the position A) is parallel to m-axis direction. A line segment passing through the substrate center and parallel to the off-direction (as an example of the line segment B) is referred to as a center line segment 52. At each of the positions on the center line segment 52, the off-direction is identical, that is, parallel to m-axis direction. The actual measurement values of the off-angles in the m-off modified substrate 42 are shown by triangles. Among these triangles, those aligned along m-axis represent the off-angles at the positions on the central line segment 52 within the error range. The central triangle 62 represents the substrate center. The off-amount at the substrate center is 0.44°. As for the m-off modified substrate 42, the actual measurement values of the off-angle are also indicated at positions shifted from the substrate center to the positive side and to the negative side in a-axis direction orthogonal to m-axis direction representing the center line segment 52.

FIG. 8 is a graph illustrating the off-amounts on the central line segments 50 to 52 on the respective substrates 40 to 42 in relation to the positions on the substrate. The horizontal axis represents the position on the substrate (Wafer position) expressed in mm, and the vertical axis represents the off-amount (|Off-angle|) expressed in °. The position on the substrate is based on the substrate center (0), and the side with the off-amount being decreasing is shown as a negative side and the side with the off-amount being increasing is shown as a positive side. The diameter of each of the substrates 40 to 42 is 2 inches.

As can be seen, on each of the central line segments 50 to 52 of the respective substrates 40 to 42, the off-amount varies monotonically from one end to the other end in proportional to the distance from the one end, in other words, the off-amount varies linearly. In addition, it is noted that each of the substrates 40 to 42 has a different range of the off-amounts (distribution width).

Since the off-amount characteristically varies linearly as described above, the off-amount across the entire central line segment (on the line segment B) may be calculated by fitting the several actual measurement values of the off-amount.

In this experimental example, the range of the off-amount of the m-off modified substrate 42 is included in the range of the off-amount of the a-off substrate 40 and the m-off substrate 41. However, the range of the a-off substrate 40 and the range of the off-amount of the m-off substrate 41 are different from each other and have non-shared portions. In other words, since the substrate 40 having a range of the off-amount on the relatively higher off-amount side and the substrate 41 having a range of off-amount on the relatively lower off-amount side are used in combination, the range of the off-amount may be enlarged compared to the case using only one substrate, for example.

With the off-amount around 0°, the surface of the grown epi-layer is roughened (rougher morphology). From this point of view, the off-amount is preferably, for example, 0.1° or more all over the main surface of the substrate.

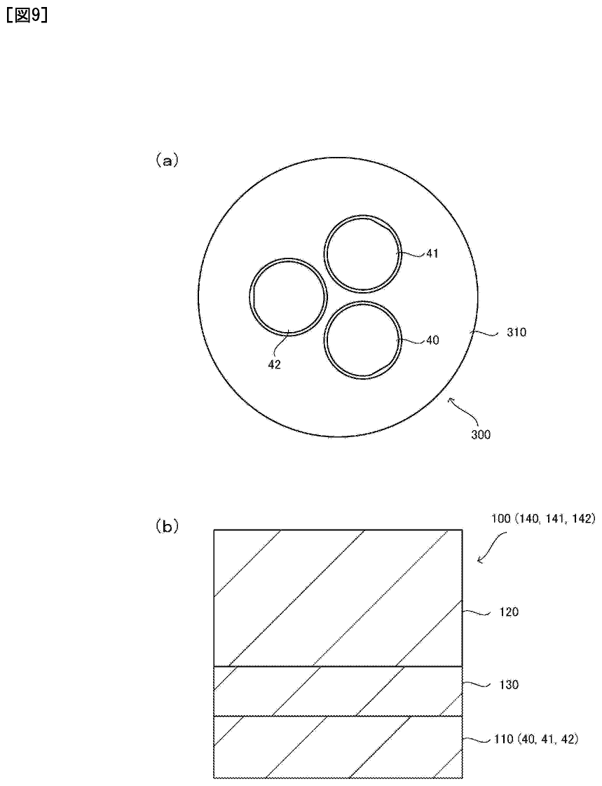

Next, a laminate will be explained in which an epi-layer is grown above each of the substrates 40 to 42. FIG. 9(a) is a schematic plan view illustrating a growth step of an epi-layer, and FIG. 9(b) is a schematic cross-sectional view illustrating the laminate.

In order to suppress variations in growth conditions, the substrates 40 to 42 were placed on the susceptor 310 of the MOVPE apparatus 300, and epi-layers were grown simultaneously on the substrates 40 to 42. Trimethylgallium (TMG) gas was used as a group-III organic source gas. Ammonia (NH₃) gas was used as a N source gas. Si was used as an n-type impurity, and silane (SiH₄) gas was used as a Si source gas.

The laminate 100 has the substrate 110 (40, 41, 42) and the epi-layer 120. In the laminate 100 manufactured in this experimental example, there is an additional intervening epi-layer 130 between the substrate 110 and the epi-layer 120. The substrate 110 includes GaN and has Si concentration of 1×10¹⁸ cm⁻³ and thickness of 400 μm. The additional substrate 130 includes GaN and has Si concentration of 2×10¹⁸ cm⁻³ and thickness of 2 μm. The substrate 120 includes GaN and has Si concentration of 9×10¹⁵ cm⁻³ (designed value) and thickness of 13 μm.

Thus, as the laminates 100, the following three types of laminates were prepared: a laminate 140 having the a-off substrate 40 as the substrate 110, a laminate 141 having the m-off substrate 41 as the substrate 110, and a laminate 142 having the m-off modified substrate 42 as the substrate 110.

Next, the result of investigation on the manufactured laminates 140 to 142 for the relationship between the off-angle and the relative yellow intensity will be explained.

PL mapping measurement of the epi-layer 120 was conducted using LabRAM HR Evolution manufactured by HORIBA, Ltd. As the excitation light source, a He—Cd laser (wavelength, 325 nm; power, 1.25 mW) was used. The spot size of the laser was 5 μm in diameter. Therefore, the irradiation intensity is 6.4×10³ Wcm⁻². PL mapping measurement was conducted while moving the measurement position at intervals of 500 μm.

The relative yellow intensity was calculated as a rate Int_{YL}/Int_{NBE} of the emission intensity Int_{YL} of yellow emission of the peak at 2.2 eV to the emission intensity Int_{NBE} of the band edge emission of the peak at 3.4 eV.

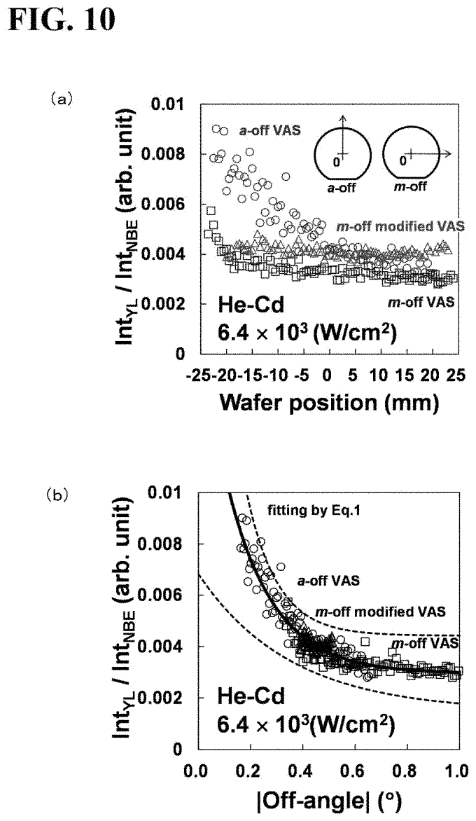

FIG. 10(a) is a graph illustrating the relative yellow intensity of the epi-layer 120 on the center line segments 50 to 52 of the laminates 140 to 142 plotted against the position on the substrate. The horizontal axis represents the position on the substrate (Wafer position) expressed in mm, and the vertical axis represents relative yellow intensity (Int_{YL}/Int_{NBE}) expressed in arbitrary unit (arb. unit).

FIG. 10 (b) is a graph illustrating the relative yellow intensity on the central line segments 50 to 52 of the epi-layer 120 of each of the laminates 140 to 142 plotted against the off-amount. The horizontal axis represents the off-amount (|Off-angle|) expressed in °, and the vertical axis represents relative yellow intensity (Int_{YL}/Int_{NBE}) expressed in arbitrary unit (arb. unit).

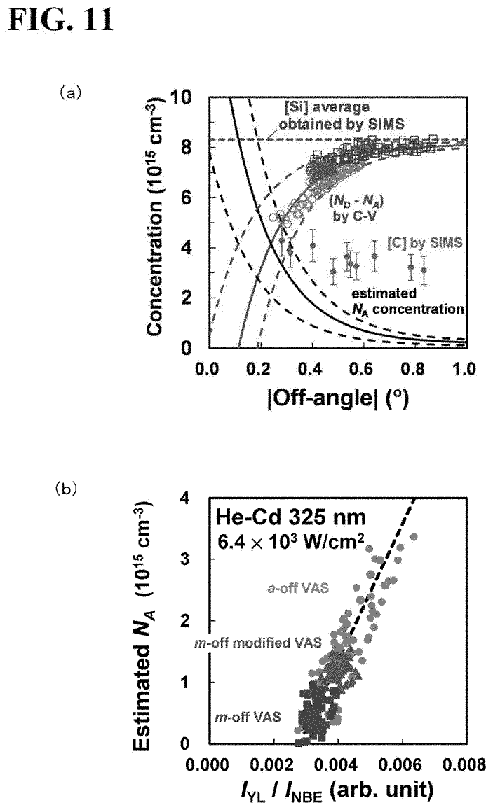

In both FIGS. 10 (a) and 10 (b), the results of the laminate 140 using the a-off substrate 40 are indicated by circles, the results of the laminate 141 using the m-off substrate 41 are indicated by squares, and the results of the laminate 142 using the m-off modified substrate 42 are indicated by triangles. Such a way of indication applies to FIG. 11(a) and FIG. 11(b) shown below.

As shown in FIG. 10 (a), a tendency that the more the position on the substrate moves toward the side where the off-amount is increasing, the more the relative yellow intensity is decreased can be read from the result of the relative yellow intensity plotted against the position on the substrate. However, it is difficult to read the characteristics common to the laminates 140 to 142 from the figure.

The inventors of the present invention tried to indicate the relative yellow intensity in relation to the off-amount, as in FIG. 10 (b). As a result, the inventors found a characteristic common to laminates 140 to 142 that equal off-amount corresponds to equal relative yellow intensity. For example, all of the laminates 140 to 142 have positions where the off-amount is 0.4° (see FIG. 8), and the relative yellow intensities at the positions where the off-amount is 0.4° are equal despite some error.

The results for the laminate 140 show the characteristic at the measurement position where the off-direction is in a-axis direction, and the results for the laminate 141 and 142 show the characteristics at the measurement position where the off-direction is in m-axis direction. In general, the various characteristics of the group-III nitride semiconductors may differ between a-axis direction and m-axis direction. Anisotropy in characteristics may occur in a-axis direction and in m-axis direction. Moreover, how the anisotropy occurs may differ for every characteristic. For this reason, it is not obvious whether the relative yellow intensities are equal even when the off-amounts are equal between the measurement positions in a-axis direction and the measurement positions in m-axis direction.

The inventors of the present invention found from the present experimental example that the relative yellow intensity of the epi-layer 120 is determined depending on the off-amount, does not depend on the off-direction, that is, does not depend on whether the off-direction is in a-axis direction or in m-axis direction. In other words, the inventors found that the off-amount and the relative yellow intensity have a correspondence relationship which does not depend on the off-direction.

For both of the measurement position where the off-direction is in a-axis direction and the measurement position where the off-direction is in m-axis direction, the relative yellow intensity depends on the off-amount. It means that the off-direction has both a-axis direction ingredient and m-axis direction ingredient, and similarly for the measurement position with intermediate characteristic between a-axis direction and m-axis direction, the relative yellow intensity id determined by the off-amount. In other words, the relative yellow intensity depends on the off-amount also at the measurement positions other than those on the center line segments 50 to 52 of the laminates 140 to 142.

The inventors of the present invention also found that the correspondence relationship has a tendency such that as the off-amount is increased, the relative yellow intensity is decreased, with a degree of the decrease in the relative yellow intensity becoming small. The inventors of the present invention further found that such a tendency, that is, relative yellow intensity Int(θ_{off}) is approximately expressed by the equation (1) using the off-amount θ_{off}, attenuation constant λ, critical off-amount θ₀, constant A and Int₀.

The approximate curve shown by a solid line in FIG. 10 (b) is a curve obtained from equation (1). In the present example, decay constant λ is 5.67±0.24 (in) 1/°, critical off-amount θ₀ is 0.091 (in)°, and constant A is 0.00827±0.00025 (in arbitrary unit), constant Int₀ is 0.0029 ±0.00006 (in arbitrary unit). Curves in which these parameters, λ, A, and Int₀ are respectively increased by 50% and decreased by 50% are indicated by dashed lines.

In the present experimental example, since the laminate 100 (140) including the substrate 40 having a range of the off amount on the relatively lower off-amount side and the laminate 100 (141) including the substrate 41 having a range of the off-amount on the relatively higher off-amount side are used in combination, the range of the off-amount to be measured may be enlarged compared to the case using only one laminate 100, for example only one of the laminates 140 and 141. In this way, the correspondence relationship for a wide range of off-amount can be obtained with high accuracy.

Thus obtained correspondence relationship between the off-amount and the relative yellow intensity can be used, for example, to inspect the crystal quality of the epi-layer of the group-III nitride laminate, as explained in the afore-mentioned embodiments and the like.

Next, the result of investigation on the manufactured laminates 140 to 142 for the relationship between the off-angle and the carrier concentration will be explained.

The carrier concentration of the epi layer 120 was measured by a non-contact CV measurement. Here, the “carrier concentration” is the concentration of the added n-type impurities, that is, a net donor concentration N_{D}−N_{A} obtained by subtracting the acceptor concentration N_{A} from the donor concentration N_{D} determined by the Si concentration. The non-contact C-V measurement is conducted with FAaST-210 manufactured by Semilab Semiconductor Physics Laboratory Co. Ltd. In addition, the Si concentration and the carbon (C) concentration were also measured by SIMS.

FIG. 11 (a) is a graph illustrating the carrier concentration in the epi-layer 120 of each of the laminates 140 to 142 plotted against the off-amount. The horizontal axis represents the off-amount (|Off-angle|) expressed in °, and the vertical axis represents the concentration expressed in 10¹⁵ cm⁻³. FIG. 11(a) shows the Si concentration and the C concentration along with the acceptor concentration.

The average Si concentration ([Si]) in the epi-layer 120 measured by SIMS was 8.32×10¹⁵ cm⁻³. The off-amount dependency of the Si concentration was hardly observed. Accordingly, the acceptor concentration N_{A} can be estimated by subtracting from the Si concentration the carrier concentration N_{D}−N_{A} measured by a non-contact C-V.

The inventors of the present invention found that the correspondence relationship between the off-amount and the carrier concentration N_{D}−N_{A} has a tendency such that as the off-amount is increased, the carrier concentration N_{D}−N_{A} is increased, with a degree of the increase in the carrier concentration N_{D}−N_{A} becoming small. In other words, the inventors of the present invention found that the correspondence relationship between the off-amount and the acceptor concentration N_{A} has a tendency such that as the off-amount is increased, the acceptor concentration N_{A} is decreased, with a degree of the decrease in the acceptor concentration N_{A} becoming small.

Regarding to the acceptor concentration in the epi-layer 120, the laminates 140 to 142 may be identified as group-III nitride laminates in which the correspondence relationship between the off-amount and the acceptor concentration has a tendency such that as the off-amount is increased, the acceptor concentration is decreased, with a degree of the decrease in the acceptor concentration becoming small.

The inventors of the present invention further found that such a tendency regarding to the acceptor concentration N_{A} may be approximately expressed by equation (2) using off-amount θ_{off}, decay constant λ, critical off-amount θ₀, constant B, and N_{A0}. Here, decay constant λ, and critical off-amount θ₀ respectively coincide with decay constant λ and critical off-amount θ₀ in the approximate equation (1) regarding to the relative yellow intensity.

[Eq. 2]

N_{A}(θ_{off})=Bexp[−λ(θ_{off}−θ₀)]+N_{A0} (2)

The approximate curve of the acceptor concentration N_{A} shown by a solid line in FIG. 11(a) is a curve obtained from equation (2). In the present example, decay constant λ is 5.67±0.24 (in)1/°), critical off-amount θ₀ is 0.091 (in °), and constant B is 9.21±0.74 (in 10¹⁵ cm⁻³), constant N_{A0} is 0.86±0.09 (in 10¹⁵ cm⁻³). As examples of a rough indication of the upper limit and the lower limit of the acceptor concentration N_{A}, a curve in which the acceptor concentration N_{A} of the approximate curve is increased by 50% and a curve in which the acceptor concentration N_{A} is decreased by 50% are shown by dashed lines. An approximate curve of the carrier concentration (net donor concentration) N_{D}−N_{A}, obtained by subtracting the acceptor concentration N_{A} of these curves from the Si concentration, a curve of a rough indication of the lower limit, and a curve of a rough indication of the upper limit are further shown in FIG. 11(a).

Although the C concentration ([C]) appears to be slightly decreased along with an increase in the off-amount, it retains substantially the same level without exhibiting such a steep drop as in the acceptor concentration N_{A}. In other words, the decrease in the C concentration is not the main factor of the decrease in the acceptor concentration N_{A} along with an increase in the off-amount. In view of the foregoing, the inventors of the present invention found that the activation rate of C as an acceptor (=acceptor concentration N_{A}/C concentration; hereinafter referred to simply as “activation rate of C”) incorporated in the epi-layer 120 decreases along with an increase in the off-amount. In this example, it is estimated that, with the off-amount of 0.25°, almost all C becomes an acceptor; with the off-amount of 0.4°, about fifty percent of C becomes an acceptor; and with the off-amount of 0.8°, about ten percent of C becomes an acceptor.

Regarding the activation rate of C in the epi-layer 120, the laminates 140 to 142 may be identified as the group-III nitride laminates in which the correspondence relationship between the off-amount and the activation rate of C has a tendency such that as the off-amount is increased, the activation rate of C is decreased.

Since growth conditions may be controlled, for example, to provide the temperature conditions under which a group-III organic source gas may be sufficiently decomposed, the concentration of C to be incorporated into the epi-layer 120 may be suppressed to the order of 10¹⁵ cm⁻³. On the other hand, the Si concentration, that is, the n-type impurity concentration, in the epi-layer 120, is preferably suppressed to the order of 10¹⁵ cm⁻³ from the viewpoint of enhancing pressure resistance. Thus, in the epi-layer 120, the C concentration becomes comparable to the Si concentration. Therefore, the value of the activation rate of C will have great effect on the value of the carrier concentration. For example, when the C concentration is equal to the Si concentration, and the activation rate of C is 100%, the donor derived from Si will be offset by the acceptor derived from C. The C concentration being comparable to the Si concentration in the epi-layer 120 is defined as the C concentration being equal to or more than 1/10 of the Si concentration and equal to or less than the Si concentration.

According to the aforementioned findings, even if the C concentration is comparable to the Si concentration in the epi-layer and it is difficult to reduce the acceptor concentration by further reduction of the C concentration, appropriately high off-amount may be selected to suppress the activation rate of C, thereby reducing the acceptor concentration and increasing the carrier concentration. In other words, the n-type impurity added to the epi-layer can be efficiently utilized as a donor. A technique which can control the C-derived acceptor concentration in this way is particularly effective for precisely controlling a low carrier concentration in the epi-layer of the order of 10¹⁵ cm⁻³ or less.

For example, the activation rate of C is preferably 50% or less, and more preferably 30% or less. In an example illustrated in FIG. 11(a), when the off-amount is about 0.4° or more, the activation rate of C may be 50% or less, and when the off-amount is about 0.5° or more, the activation rate of C may be 30% or less.

According to the aforementioned findings, using a substrate in which an appropriately large off-amount is selected may provide a group-III nitride laminate having the epi-layer in which the n-type impurity concentration is in an order of 10¹⁵ cm⁻³ or less (less than 1×10¹⁶ cm⁻³), the C concentration is equal to or more than 1/10 of the n-type impurity concentration and equal to or less than the n-type impurity concentration, and the activation rate of C is preferably 50% or less and more preferably 30% or less.

Next, the result of investigation on the relationship between the relative yellow intensity and the acceptor concentration for the manufactured laminates 140 to 142 will be explained.

FIG. 11 (b) is a graph illustrating the acceptor concentration in the epi-layer 120 of each of the laminates 140 to 142 plotted against the relative yellow intensity.

The horizontal axis represents the relative yellow intensity (Int_{YL}/Int_{NBE}) expressed in an arbitrary unit (arb. unit) and the vertical axis represents the concentration expressed in 10¹⁵ cm⁻³.

The correspondence relationship between the off-amount and the relative yellow intensity explained with reference to FIG. 10 (b) may be associated with the correspondence relationship between the off-amount and the acceptor concentration explained with reference to FIG. 11(a) using the off-amount to obtain the correspondence relationship between the relative yellow intensity and the acceptor concentration as shown in FIG. 11(b).

Regarding the epi-layer 120, since the relative yellow intensity is expressed by equation (1) using the off-amount and the acceptor concentration is expressed by equation (2) using the off-amount, the acceptor concentration varies in proportion to the relative yellow intensity as illustrated in FIG. 11(b). In other words, the laminates 140 to 142 may be identified as the group-III nitride laminates in which the correspondence relationship between the relative yellow intensity and the acceptor concentration in the epi-layer 120 is such that the acceptor concentration is proportional to the relative yellow intensity.

With correspondence relationship between the relative yellow intensity and the acceptor concentration as illustrated in FIG. 11(b) being obtained in advance, PL mapping measurement may be conducted to obtain the relative yellow intensity to estimate the acceptor concentration without conducting C-V measurement. The technique capable of obtaining the acceptor concentration by PL mapping measurement in the manner described above is very useful because it can be easily and nondestructively conducted. Similar idea may be used to obtain the carrier concentration.

### Other Embodiments

As an example of another embodiment, a group-III nitride laminate with a physical amount map will be explained, which is an aspect in which the group-III nitride laminate as described above is provided in combination with a physical amount map.

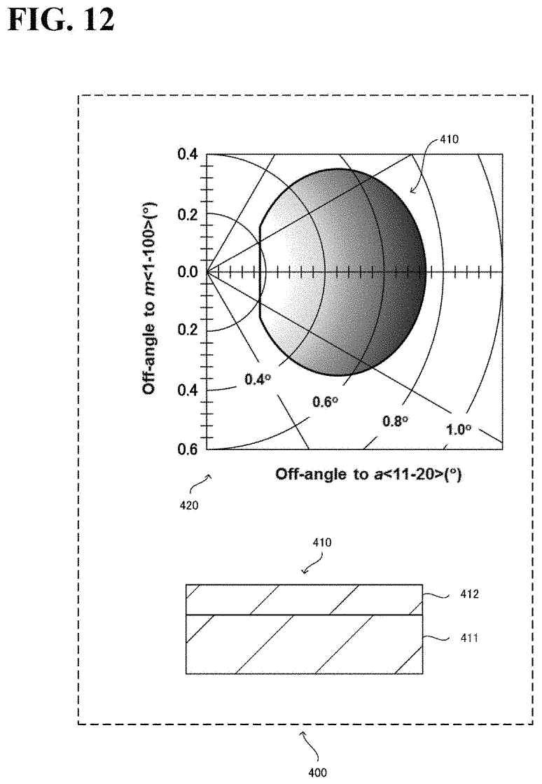

FIG. 12 is a schematic view illustrating a group-III nitride laminate with a physical amount map (which may also be referred to as a laminate with a map hereinafter) 400. The laminate with a map 400 has the laminate 410 and the physical amount map 420. The laminate 410 has the substrate 411 and the epi-layer 412. The expression “with a map” herein encompasses: (1) a case where a recording medium storing information indicating the contents of the map or a printed matter on which the map is printed is adjunct to a tray containing the laminate 410 or an enclosed item; and (2) a case where the information indicating the contents of the map is provided so as to be downloadable via the Internet, a dedicated line or the like.

The physical amount map 420 is a map that displays the physical amount of the epi-layer 412 of the laminate 410, and displays the contour of the laminate 410, the off-amount within the contour, and the physical amount within the contour. The physical amount is, for example, the relative yellow intensity, the acceptor concentration, or the activation rate of C. A physical amount map 420 illustrated in FIG. 12 is an exemplary display of the relative yellow intensity and indicates an area with higher relative yellow intensity being indicated lighter.

In the main surface of substrate 411, the positions with constant off-amounts are distributed along concentric arcs or concentric elliptic arcs (see FIG. 7 (c)). An ellipse herein may encompass a circle as a case where two foci coincide with each other. Since the relative yellow intensity is determined depending on the off-amount, the positions where the relative yellow intensity is constant will be distributed along the concentric arc or concentric elliptic arc on the epi-layer 412. On the epi-layer 412, the positions where the relative yellow intensity represents a certain constant value are distributed along an arc or an elliptic arc, and the positions where the relative yellow intensity indicates another constant value different from said constant value are distributed along another arc concentric with said arc or along another elliptic arc concentric said the elliptic arc.

Similarly, since the acceptor concentration and the activation rate of C are also determined depending on the off-amount, the positions with the acceptor concentration and the activation rate of C being constant will be distributed along the concentric arc or concentric elliptic arc on the epi-layer 412. On the epi-layer 412, the positions where the acceptor concentration represents a certain constant value are distributed along an arc or an elliptic arc, and the positions where the acceptor concentrations represents another constant value different from the constant value are distributed along another arc concentric with the arc or along another elliptic arc concentric with the elliptic arc. Further, on the epi-layer 412, the positions where the activation rate of C represents a certain constant value are distributed along an arc or an elliptic arc, and the positions where the activation rate of C represents another constant value different from the constant value are distributed along another arc concentric with said arc or along another elliptic arc concentric with said elliptic arc.

When the physical amount determined depending on the off-amount measured all over the surface of the epi-layer 412 are displayed on the physical amount map 420, the concentric circle or concentric ellipse patterns (more specifically, concentric arc or concentric elliptic patterns the centers of which are located outside of the laminate 410) are observed for the epi-layer 412 grown normally. Therefore, using the physical amount map 420, it is possible to grasp at a glance the crystal quality all over the surface of the epi-layer 412. Further, providing the laminate 410 in combination with the physical amount map 420, the quality assurance of the laminate 410 can be effectively presented.

The present invention has been explained with reference to embodiments and variations, but the present invention is not limited to them. For example, it will be apparent to those skilled in the art that various modifications, improvements, combinations, and the like can be made.

### Preferred Aspect of the Present Invention

Hereinafter, illustrative supplementary descriptions of the preferred aspects of the present invention will be given.

### (Supplementary Description 1)

A manufacturing method, inspection method, and evaluating method of a group-III nitride laminate and a manufacturing method of a semiconductor device including:

preparing (at least one) first group-III nitride laminate having a first group-III nitride substrate and a first group-III nitride epitaxial layer formed above a main surface of the first group-III nitride substrate (by metal organic vapor phase epitaxy); and

conducting photoluminescence mapping measurement at a plurality of measurement positions on the first group-III nitride epitaxial layer, where a magnitude of an off-angle (off-amount) is different, the off-angle being formed by a normal direction of the main surface of the first group-III nitride substrate and c-axis direction, to obtain a relative yellow intensity which is a rate of a yellow emission intensity to a band edge emission intensity, and obtain a correspondence relationship between a magnitude of the off-angle and the relative yellow intensity.

### (Supplementary Description 2)

The manufacturing method of the group-III nitride laminate according to supplementary description 1, further including:

preparing a second group-III nitride laminate having a second group-III nitride substrate and a second group-III nitride epitaxial layer formed above a main surface of the second group-III nitride substrate (by metal organic vapor phase epitaxy);

conducting photoluminescence mapping measurement at an inspection position on the second group-III nitride epitaxial layer, where a magnitude of an off-angle is a first magnitude of an off-angle, the off-angle being formed by a normal direction of the main surface of the second group-III nitride substrate and c-axis direction, and obtaining a relative yellow intensity which is a rate of a yellow emission intensity to a band edge emission intensity; and

comparing the relative yellow intensity obtained from the photoluminescence mapping measurement at the inspection position, with a relative yellow intensity obtained from the correspondence relationship with respect to the first magnitude of the off-angle.

### (Supplementary Description 3)

The manufacturing method of a group-III nitride laminate according to supplementary description 1 or 2, wherein a plurality of group-III nitride laminates are used as the first group-III nitride laminate.

### (Supplementary Description 4)

The manufacturing method of the group-III nitride laminate according to any one of supplementary descriptions 1 to 3,

wherein a plurality of group-III nitride laminates having a different range of the magnitude of the off-angle are used as the first group-III nitride laminate.

### (Supplementary Description 5)

The manufacturing method of the group-III nitride laminate according to any one of supplementary descriptions 1 to 4,

wherein a plurality of group-III nitride laminates having a different range of the magnitude of the off-angle on a line segment passing through the center of the first group-III nitride substrate and parallel to the orientation of the off-angle (off-direction) at the center are used as the first group-III nitride laminate.

### (Supplementary Description 6)

The manufacturing method of the group-III nitride laminate according to any one of supplementary descriptions 1 to 5,

wherein a plurality of group-III nitride laminates having a different orientation of the off-angle at the center of the first group-III nitride laminate are used as the first group-III nitride laminate.

### (Supplementary Description 7)

The manufacturing method of the group-III nitride laminate according to any one of supplementary descriptions 3 to 6,

wherein preparing the first group III nitride laminate includes simultaneously growing the group III nitride epitaxial layers of the plurality of group III nitride laminates.

### (Supplementary Description 8)

A manufacturing method, inspection method, and evaluating method of a group-III nitride laminate and a manufacturing method of a semiconductor device including:

preparing a correspondence relationship between a magnitude of an off-angle and a relative yellow intensity;

preparing a group-III nitride laminate having a group-III nitride substrate and a group-III nitride epitaxial layer formed above a main surface of the group-III nitride substrate (by metal organic vapor phase epitaxy);

conducting photoluminescence mapping measurement at an inspection position on the group-III nitride epitaxial layer, where a magnitude of an off-angle is a first magnitude of an off-angle formed by a normal direction of the main surface of the group-III nitride substrate and c-axis direction, to obtain a relative yellow intensity which is a rate of a yellow emission intensity to a band edge emission intensity; and

comparing the relative yellow intensity obtained from the photoluminescence mapping measurement at the inspection position, with a relative yellow intensity obtained from the correspondence relationship with respect to the first magnitude of the off-angle.

### (Supplementary Description 9)

The manufacturing method of the semiconductor device described in any one of supplementary descriptions 1 to 8,

wherein the correspondence relationship has a tendency such that as the magnitude of the off-angle is increased, the relative yellow intensity is decreased, with a degree of the decrease in the relative yellow intensity becoming small.

(Supplementary description 10)

The manufacturing method of the group-III nitride laminate according to any one of supplementary descriptions 1 to 9,

wherein the correspondence relationship is approximately expressed by the following equation, using exponential decay constant λ, critical magnitude of off-angle θ₀ at which exponential function argument is zero, constant A to be multiplied by exponential function, and constant Int₀ to be added to exponential function:

Int(θ_{off})=Aexp[−λ(θ_{off}−θ₀)]+Int₀ [Eq. 3]

in the equation, θ_{off} represents a magnitude of the off-angle, and Int(θ_{off}) represents a relative yellow intensity.

### (Supplementary Description 11)

The manufacturing method of the group-III nitride laminate according to any one of supplementary descriptions 1 to 10,

wherein, in the correspondence relationship, the relative yellow intensity does not depend on the orientation of the off-angle (does not depend on whether the orientation of the off-angle is in a-axis direction or in m-axis direction).

### (Supplementary Description 12)

A manufacturing method, inspection method, and evaluating method of a group-III nitride laminate and a manufacturing method of a semiconductor device including:

preparing a correspondence relationship between a magnitude of an off-angle and a relative yellow intensity;

preparing a group-III nitride laminate having a group-III nitride substrate and a group-III nitride epitaxial layer formed above a main surface of the group-III nitride substrate (by metal organic vapor phase epitaxy);

conducting at least one measurement selected from a capacitance-voltage measurement, a secondary ion mass spectrometry measurement, and a deep level transient spectroscopy measurement at a plurality of measurement positions on the group-III substrate, where a magnitude of an off-angle is different, the off-angle being formed by a normal direction of the main surface of the group-III nitride substrate and c-axis direction, and obtaining a correspondence relationship between the present measurement result and the magnitude of the off-angle; and

associating the correspondence relationship between the result of the measurement and the magnitude of the off-angle with the correspondence relationship between the magnitude of the off-angle and the relative yellow intensity using the magnitude of the off-angle.

### (Supplementary Description 13)

A manufacturing method, inspection method, and evaluating method of a group-III nitride laminate and a manufacturing method of a semiconductor device including:

preparing a first correspondence relationship which is a correspondence relationship between a magnitude of an off-angle and a relative yellow intensity;

preparing a second correspondence relationship which is a correspondence relationship between a magnitude of an off-angle and a physical amount obtained by at least one measurement selected from a capacitance-voltage measurement, a secondary ion mass spectrometry measurement, and a deep level transient spectroscopy measurement;

associating the first correspondence relationship with the second correspondence relationship using a magnitude of an off-angle to obtain a third correspondence relationship which is a correspondence relationship between a relative yellow intensity and the physical amount;

preparing a group-III nitride laminate having a group-III nitride substrate and a group-III nitride epitaxial layer formed above a main surface of the group-III nitride substrate;

conducting photoluminescence mapping measurement at an inspection position defined on the group-III nitride epitaxial layer to obtain a relative yellow intensity which is a rate of a yellow emission intensity to a band edge emission intensity; and estimating the physical amount at the inspection position based on the relative yellow intensity obtained from the photoluminescence mapping measurement at the inspection position and the third correspondence relationship.

### (Supplementary Description 14)

A manufacturing method, inspection method, and evaluating method of a group-III nitride laminate and a manufacturing method of a semiconductor device including:

preparing a correspondence relationship between a relative yellow intensity and a physical amount obtained by at least one measurement selected from a capacitance-voltage measurement, a secondary ion mass spectrometry measurement, and a deep level transient spectroscopy measurement;

preparing a group-III nitride laminate having a group-III nitride substrate and a group-III nitride epitaxial layer formed above a main surface of the group-III nitride substrate;

conducting photoluminescence mapping measurement at an inspection position defined on the group-III nitride epitaxial layer, and obtaining a relative yellow intensity which is a rate of a yellow emission intensity to a band edge emission intensity; and

estimating the physical amount at the inspection position based on the relative yellow intensity obtained from photoluminescence mapping measurement at the inspection position and the correspondence relationship.

### (Supplementary Description 15)

A group-III nitride laminate including a group-III nitride substrate and a group-III nitride epitaxial layer formed above a main surface of the first group-III nitride substrate (by metal organic vapor phase epitaxy),

in which, regarding a relative yellow intensity which is a rate of a yellow emission intensity to a band edge emission intensity in photoluminescence in the group-III nitride epitaxial layer,

a correspondence relationship between a magnitude of an off-angle formed by a normal direction of the main surface of the group-III nitride substrate and c-axis direction, and a relative yellow intensity has a tendency such that as the magnitude of the off-angle is increased, the relative yellow intensity is decreased, with a degree of the decrease in the relative yellow intensity becoming small.

### (Supplementary Description 16)

The group-III nitride laminate according to supplementary description 15,

wherein the relative yellow intensity does not depend on an orientation of the off-angle in the correspondence relationship between the magnitude of the off-angle and the relative yellow intensity.

### (Supplementary Description 17)

The group-III nitride laminate according to supplementary description 15 or 16,

wherein the correspondence relationship between the magnitude of the off-angle and the relative yellow intensity is approximately expressed by the following equation, using exponential decay constant λ, critical magnitude off-angle θ₀ at which exponential function argument is zero, constant A to be multiplied by exponential function, and constant Int₀ to be added to exponential function:

Int(θ_{off})=Aexp[−λ(θ_{off}−θ₀)]+Int₀ [Eq. 4]

in the equation, θ_{off} represents a magnitude of the off-angle, and Int(θ_{off}) represents a relative yellow intensity.

### (Supplementary Description 18)

The group-III nitride laminate according to supplementary description 17,

wherein the measured relative yellow intensity distributes within a range equal to or more than a lower limit and equal to or less than an upper limit, the lower limit being defined by assigning to the equation the values 50% lower than the decay constant λ, the constant A, and the constant Int₀, which are defined to approximately express the correspondence relationship between the magnitude of the off-angle and the relative yellow intensity, and the upper limit being defined by assigning to the equation the values 50% higher than each of the decay constant λ, the constant A, and the constant Int₀, which are defined to approximately express the correspondence relationship.

### (Supplementary Description 19)

The group-III nitride laminate according to any one of supplementary descriptions 15 to 18,

wherein an n-type impurity is added to the group-III nitride epitaxial layer,

and regarding an acceptor concentration of the group-III nitride epitaxial layer,

the correspondence relationship between the magnitude of the off-angle and the acceptor concentration has a tendency such that as the magnitude of the off-angle is increased, the acceptor concentration is decreased, with a degree of the decrease in the acceptor concentration becoming small.

### (Supplementary Description 20)

The group-III nitride laminate according to supplementary description 19,

wherein the correspondence relationship between the magnitude of the off-angle and the acceptor concentration is approximately expressed by the following equation, using the decay constant λ, the critical magnitude off-angle θ₀, constant B to be multiplied by exponential function, and constant N_{A0} to be added to exponential function:

N_{A}(θ_{off})=Bexp[−λ(θ_{off}−θ₀)]+N_{A0} [Eq. 5]

in the equation, θ_{off} represents a magnitude of the off-angle and N_{A}(θ_{off}) represents the acceptor concentration.

### (Supplementary Description 21)

The group-III nitride laminate according to supplementary description 19 or 20,

wherein the correspondence relationship between the relative yellow intensity and the acceptor concentration has a tendency such that the acceptor concentration is proportional to the relative yellow intensity.

### (Supplementary Description 22)

The group-III nitride laminate according to any one of supplementary descriptions 15 to 21,

wherein the concentration of the n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and

regarding an activation rate of carbon which is a rate of an acceptor concentration to the carbon concentration in the group-III nitride epitaxial layer,

the correspondence relationship between the off-angle and the activation rate of carbon has a tendency such that as the magnitude of the off-angle is increased, the activation rate of carbon is decreased.

### (Supplementary Description 23)

A group-III nitride laminate having a group-III nitride substrate and a group-III nitride epitaxial layer formed above a main surface of the first group-III nitride substrate (by metal organic vapor phase epitaxy),

in which the concentration of an n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and

regarding an activation rate of carbon which is a rate of an acceptor concentration to the carbon concentration in the group-III nitride epitaxial layer,

the correspondence relationship between the off-angle formed by a normal direction of the main surface of the group-III nitride substrate and c-axis direction and the activation rate of carbon has a tendency such that as the magnitude of the off-angle is increased, the activation rate of carbon is decreased.

### (Supplementary Description 24)

A group-III nitride laminate having a group-III nitride substrate and a group-III nitride epitaxial layer formed above a main surface of the first group-III nitride substrate (by metal organic vapor phase epitaxy),

in which the concentration of a n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and

an activation rate of carbon which is a rate of an acceptor concentration to the carbon concentration in the group-III nitride epitaxial layer is preferably 50% or less, and more preferably 30% or less.

### (Supplementary Description 25)

A group-III nitride laminate having a group-III nitride substrate and a group-III nitride epitaxial layer formed above a main surface of the first group-III nitride substrate (by metal organic vapor phase epitaxy),

in which, regarding a relative yellow intensity which is a rate of a yellow emission intensity to a band edge emission intensity in photoluminescence in the group-III nitride epitaxial layer,

positions where the relative yellow intensity shows a first constant value are distributed along a first arc or a first elliptic arc, and positions where the relative yellow intensity shows a second constant value different from the first constant value are distributed along a second arc concentric with the first arc or along a second elliptic arc concentric with the first elliptic arc, on the group-III nitride epitaxial layer.

### (Supplementary Description 26)

The group-III nitride laminate according to supplementary description 25,

wherein an n-type impurity is added to the group-III nitride epitaxial layer,

and regarding an acceptor concentration of the group-III nitride epitaxial layer,

positions where the acceptor concentration shows a third constant value are distributed along a third arc (which is concentric with the first arc) or a third elliptic arc (which is concentric with the first elliptic arc), and positions where the acceptor concentration shows a fourth constant value different from the third constant value are distributed along a fourth arc concentric with the third arc or along a fourth elliptic arc concentric with the third elliptic arc, on the group-III nitride epitaxial layer.

### (Supplementary Description 27)

The group-III nitride laminate according to supplementary description 26,

wherein the concentration of the n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and

regarding an activation rate of carbon which is a rate of an acceptor concentration to the carbon concentration in the group-III nitride epitaxial layer,

positions where the activation rate of carbon shows a fifth constant value are distributed along a fifth arc (concentric with the first arc) or a fifth elliptic arc (concentric with the first elliptic arc), and positions where the activation rate of carbon shows a sixth constant value different from the fifth constant value are distributed along a sixth arc concentric with the fifth arc or along a sixth elliptic arc concentric with the fifth elliptic arc, on the group-III nitride epitaxial layer.

### (Supplementary Description 28)

A group-III nitride laminate having a group-III nitride substrate and a group-III nitride epitaxial layer formed above a main surface of the first group-III nitride substrate (by metal organic vapor phase epitaxy),

in which the concentration of the n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and

regarding an activation rate of carbon which is a rate of an acceptor concentration to the carbon concentration in the group-III nitride epitaxial layer,

positions where the activation rate of carbon shows a first constant value are distributed along a first arc or a first elliptic arc, and positions where the activation rate of carbon shows a second constant value different from the first constant value are distributed along a second arc concentric with the first arc or along a second elliptic arc concentric with the first elliptic arc, on the group-III nitride epitaxial layer.

### (Supplementary Description 29)

The group-III nitride laminate according to any one of supplementary descriptions 15 to 28,

wherein a maximum defect density is 5×10⁶ cm ⁻² or less, more preferably equal to or less than 10 times an average defect density, and still more preferably equal to or less than 10 times a minimum defect density, in the main surface of the group-III nitride substrate.

### (Supplementary Description 30)

The group-III nitride laminate according to any one of supplementary descriptions 15 to 29,

wherein, at each position located on a line segment B passing through a position A and parallel to the orientation of the off-angle at the position A which is defined on the main surface of the group-III nitride substrate, the orientation of the off-angle is the same as the orientation of the off-angle at the position A and the magnitude of the off-angle varies from one end toward the other end of the line segment B monotonically in proportion to the distance from the one end.

### (Supplementary Description 31)

The group-III nitride laminate according to any one of supplementary descriptions 15 to 30,

which is a group-III nitride laminate with a physical amount map further including a physical amount map illustrating a contour of the group-III nitride laminate, the magnitude of the off-angle within the contour, and the physical amount of the group-III nitride epitaxial layer within the contour.

### (Supplementary Description 32)

The group-III nitride laminate according to any one of supplementary descriptions 15 to 31

wherein the group-III nitride substrate has no position with a magnitude of the off-angle of zero all over the main surface.

### (Supplementary Description 33)

The group-III nitride laminate according to any one of supplementary descriptions 15 to 32,

wherein the magnitude of the off-angle of the group-III nitride substrate is 0.1° or more all over the main surface.

### (Supplementary Description 34)

The group-III nitride laminate according to any one of supplementary descriptions 15 to 33,

wherein the group-III nitride substrate, and the group-III nitride epitaxial layer have n-type conductivity.

### (Supplementary Description 35)

The group-III nitride laminate according to any one of supplementary descriptions 15 to 34,

wherein an n-type impurity is added to the group-III nitride epitaxial layer, for example, at a concentration of 3×10¹⁵ cm⁻³ or more and 5×10¹⁶ cm⁻³ or less.

### EXPLANATION OF REFERENCE NUMERALS

100 REFERENCE LAMINATE
200 INSPECTION LAMINATE
110, 210 SUBSTRATE
111, 211 MAIN SURFACE
120, 220 EPI-LAYER
121, 221 SURFACE (OF EPI-LAYER)
122 MEASUREMENT POSITION
222 INSPECTION POSITION
40 A-OFF SUBSTRATE
41 M-OFF SUBSTRATE
42 M-OFF MODIFIED SUBSTRATE
400 LAMINATE WITH MAP
410 LAMINATE
420 PHYSICAL AMOUNT MAP

What is claimed is:

1-5. (canceled)

6. A group-III nitride laminate comprising a group-III nitride substrate and a group-III nitride epitaxial layer formed above a main surface of the group-III nitride substrate;
in which, regarding a relative yellow intensity which is a rate of a yellow emission intensity to a band edge emission intensity in photoluminescence in the group-III nitride epitaxial layer,
a correspondence relationship between a magnitude of an off-angle formed by a normal direction of the main surface of the group-III nitride substrate and c-axis direction, and the relative yellow intensity has a tendency such that as the magnitude of the off-angle is increased, the relative yellow intensity is decreased, with a degree of the decrease in the relative yellow intensity becoming small.

7. The group-III nitride laminate according to claim 6,
wherein the relative yellow intensity does not depend on an orientation of the off-angle in the correspondence relationship between the magnitude of the off-angle and the relative yellow intensity.

8. The group-III nitride laminate according to claim 6,
wherein the correspondence relationship between the magnitude of the off-angle and the relative yellow intensity is approximately expressed by the following equation, using exponential decay constant λ, critical magnitude off-angle θ₀ at which exponential function argument is zero, constant A to be multiplied by exponential function, and constant Int₀ to be added to exponential function:
Int(θ_{off})=Aexp[−λ(θ_{off}−θ₀)]+Int₀ [Eq. 1]
in the equation, θ_{off} represents the magnitude of the off-angle, and Int(θ_{off}) represents the relative yellow intensity.

9. The group-III nitride laminate according to claim 6,
wherein an n-type impurity is added to the group-III nitride epitaxial layer,
and regarding an acceptor concentration of the group-III nitride epitaxial layer,
the correspondence relationship between the magnitude of the off-angle and the acceptor concentration has a tendency such that as the magnitude of the off-angle is increased, the acceptor concentration is decreased, with a degree of the decrease in the acceptor concentration becoming small.

10. The manufacturing method of the group-III nitride laminate according to claim 9,
wherein the correspondence relationship between the magnitude of the off-angle and the acceptor concentration is approximately expressed by the following equation, using the decay constant λ, the critical magnitude off-angle θ₀, constant B to be multiplied by exponential function, and constant N_{A0} to be added to exponential function:
N_{A}(θ_{off})=Bexp[−λ(θ_{off}−θ₀)]+N_{A0} [Eq. 2]
in the equation, θ_{off} represents the magnitude of the off-angle and N_{A} (θ_{off}) represents the acceptor concentration.

11. The group-III nitride laminate according to claim 9,
wherein the concentration of the n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and
regarding an activation rate of carbon which is a rate of the acceptor concentration to the carbon concentration in the group-III nitride epitaxial layer,
the correspondence relationship between the off-angle and the activation rate of carbon has a tendency such that as the magnitude of the off-angle is increased, the activation rate of carbon is decreased.

12. A group-III nitride laminate comprising a group-III nitride substrate and a group-III nitride epitaxial layer formed above a main surface of the group-III nitride substrate,
in which, regarding a relative yellow intensity which is a rate of a yellow emission intensity to a band edge emission intensity in photoluminescence in the group-III nitride epitaxial layer,
positions where the relative yellow intensity shows a first constant value are distributed along a first arc or a first elliptic arc, and positions where the relative yellow intensity shows a second constant value different from the first constant value are distributed along a second arc concentric with the first arc or along a second elliptic arc concentric with the first elliptic arc, on the group-III nitride epitaxial layer.

13. The group-III nitride laminate according to claim 12,
wherein an n-type impurity is added to the group-III nitride epitaxial layer,
and regarding an acceptor concentration of the group-III nitride epitaxial layer,
positions where the acceptor concentration shows a third constant value are distributed along a third arc or a third elliptic arc, and positions where the acceptor concentration shows a fourth constant value different from the third constant value are distributed along a fourth arc concentric with the third arc or along a fourth elliptic arc concentric with the third elliptic arc, on the group-III nitride epitaxial layer.

14. The group-III nitride laminate according to claim 13,
wherein a concentration of the n-type impurity is less than 1×10¹⁶ cm⁻³, a carbon concentration is equal to or more than 1/10 of the concentration of the n-type impurity and equal to or less than the concentration of the n-type impurity in the group-III nitride epitaxial layer, and
regarding an activation rate of carbon which is a rate of the acceptor concentration to the carbon concentration in the group-III nitride epitaxial layer,
positions where the activation rate of carbon shows a fifth constant value are distributed along a fifth arc or a fifth elliptic arc, and positions where the activation rate of carbon shows a sixth constant value different from the fifth constant value are distributed along a sixth arc concentric with the fifth arc or along a sixth elliptic arc concentric with the fifth elliptic arc, on the group-III nitride epitaxial layer.

15. The group-III nitride laminate according to claim 6,
wherein a maximum defect density is 5×10⁶ cm ⁻² or less in the main surface of the group-III nitride substrate.

16. The group-III nitride laminate according to claim 6,
wherein, at each position located on a line segment B passing through a position A and parallel to an orientation of the off-angle at the position A which is defined on the main surface of the group-III nitride substrate, the orientation of the off-angle is identical to the orientation of the off-angle at the position A and the magnitude of the off-angle varies from one end toward the other end of the line segment B monotonically in proportion to a distance from the one end.

17. The group-III nitride laminate according to claim 6,
which is a group-III nitride laminate with a physical amount map further comprising a physical amount map illustrating a contour of the group-III nitride laminate, the magnitude of the off-angle within the contour, and the physical amount of the group-III nitride epitaxial layer within the contour.

18. The group-III nitride laminate according to claim 12,
wherein a maximum defect density is 5×10⁶ cm⁻² or less in the main surface of the group-III nitride substrate.

19. The group-III nitride laminate according to claim 12,
wherein, at each position located on a line segment B passing through a position A and parallel to an orientation of the off-angle at the position A which is defined on the main surface of the group-III nitride substrate, the orientation of the off-angle is identical to the orientation of the off-angle at the position A and the magnitude of the off-angle varies from one end toward the other end of the line segment B monotonically in proportion to a distance from the one end.

20. The group-III nitride laminate according to claim 12,
which is a group-III nitride laminate with a physical amount map further comprising a physical amount map illustrating a contour of the group-III nitride laminate, the magnitude of the off-angle within the contour, and the physical amount of the group-III nitride epitaxial layer within the contour.
